(19) United States
(12) Patent Application Publication
(10) Pub. No.: US 2026/0206291 A1
(43) Pub. Date: Jul. 16, 2026

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Ming-Heng TSAI, Taipei City (TW); Ta-Chun LIN, Hsinchu (TW)

(73) Assignee: Taiwan Semiconductor Manufacturing Company, Ltd., Hsinchu (TW)

(21) Appl. No.: 19/025,167

(22) Filed: Jan. 16, 2025

(51) Int. Cl. H10D 84/01; H10D 84/85

(52) U.S. Cl. CPC H10D 84/0186; H10D 84/017; H10D 84/0179; H10D 84/851

(57) ABSTRACT

A method for forming a semiconductor structure is provided. The method includes forming a first transistor and a second transistor on a substrate, respectively. The first transistor includes a first source/drain feature adjoining first channel layers and a first gate stack surrounding the first channel layers. The second transistor includes a second source/drain feature adjoining second channel layers, and a second gate stack surrounding the second channel layers. The method further includes forming a first contact plug that partially passes through the first source/drain feature from the backside surface of the first source/drain feature, and forming a second contact plug that partially passes through the second source/drain feature from the backside surface of the second source/drain feature. The first contact plug is shallower than the second contact plug.

### BACKGROUND

The electronics industry is experiencing an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device that has been introduced is the gate-all around transistor (GAA). The GAA device gets its name from the gate structure, which can extend around the channel region and provide access to the channel on two or four sides. GAA devices are compatible with conventional complementary metal-oxide-semiconductor (CMOS) processes, and their structure allows them to be aggressively scaled-down while maintaining gate control and mitigating SCEs. In conventional processes, GAA devices provide a channel in a silicon nanowire. However, integration of fabrication of the GAA features around the nanowire can be challenging. For example, while current methods have been satisfactory in many respects, continued improvements are still needed.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a perspective view of a semiconductor structure, in accordance with some embodiments of the disclosure.

FIG. 2 is a layout of a semiconductor structure, in accordance with some embodiments.

FIGS. 3A-1 and 3A-2 are cross-sectional views of the semiconductor structure at an intermediate stage corresponding to lines X1-X1 and X2-X2 and lines Y1-Y1 and Y2-Y2 of FIG. 2, in accordance with some embodiments of the disclosure.

FIGS. 3B-1 and 3B-2 are cross-sectional views of the semiconductor structure at an intermediate stage corresponding to lines X1-X1 and X2-X2 and lines Y1-Y1 and Y2-Y2 of FIG. 2, in accordance with some embodiments of the disclosure.

FIGS. 3C-1 and 3C-2 are cross-sectional views of the semiconductor structure at an intermediate stage corresponding to lines X1-X1 and X2-X2 and lines Y1-Y1 and Y2-Y2 of FIG. 2, in accordance with some embodiments of the disclosure.

FIGS. 3D-1 and 3D-2 are cross-sectional views of the semiconductor structure at an intermediate stage corresponding to lines X1-X1 and X2-X2 and lines Y1-Y1 and Y2-Y2 of FIG. 2, in accordance with some embodiments of the disclosure.

FIGS. 3E-1 and 3E-2 are cross-sectional views of the semiconductor structure at an intermediate stage corresponding to lines X1-X1 and X2-X2 and lines Y1-Y1 and Y2-Y2 of FIG. 2, in accordance with some embodiments of the disclosure.

FIGS. 3F-1 and 3F-2 are cross-sectional views of the semiconductor structure at an intermediate stage corresponding to lines X1-X1 and X2-X2 and lines Y1-Y1 and Y2-Y2 of FIG. 2, in accordance with some embodiments of the disclosure.

FIGS. 3G-1 and 3G-2 are cross-sectional views of the semiconductor structure at an intermediate stage corresponding to lines X1-X1 and X2-X2 and lines Y1-Y1 and Y2-Y2 of FIG. 2, in accordance with some embodiments of the disclosure.

FIGS. 3H-1 and 3H-2 are cross-sectional views of the semiconductor structure at an intermediate stage corresponding to lines X1-X1 and X2-X2 and lines Y1-Y1 and Y2-Y2 of FIG. 2, in accordance with some embodiments of the disclosure.

FIGS. 3I-1 and 3I-2 are cross-sectional views of the semiconductor structure at an intermediate stage corresponding to lines X1-X1 and X2-X2 and lines Y1-Y1 and Y2-Y2 of FIG. 2, in accordance with some embodiments of the disclosure.

FIGS. 4-1 and 4-2 are a modification of the semiconductor structure of FIGS. 3I-1 and 3I-2, in accordance with some embodiments of the disclosure.

FIG. 5 is a modification of the semiconductor structure of FIG. 3I-1, in accordance with some embodiments of the disclosure.

FIGS. 6-1 and 6-2 are a modification of the semiconductor structure of FIGS. 3I-1 and 3I-2, in accordance with some embodiments of the disclosure.

FIGS. 7-1 and 7-2 are a modification of the semiconductor structure of FIGS. 3I-1 and 3I-2, in accordance with some embodiments of the disclosure.

FIGS. 8-1 and 8-2 are a modification of the semiconductor structure of. FIGS. 3I-1 and 3I-2, in accordance with some embodiments of the disclosure.

FIG. 9A is a cross-sectional view of the semiconductor structure at an intermediate stage corresponding to lines X1-X1 and X2-X2 of FIG. 2, in accordance with some embodiments of the disclosure.

FIG. 9B is a cross-sectional view of the semiconductor structure at an intermediate stage corresponding to lines X1-X1 and X2-X2 of FIG. 2, in accordance with some embodiments of the disclosure.

FIG. 9C is a cross-sectional view of the semiconductor structure at an intermediate stage corresponding to lines X1-X1 and X2-X2 of FIG. 2, in accordance with some embodiments of the disclosure.

FIG. 10A is a cross-sectional view of the semiconductor structure at an intermediate stage corresponding to lines X1-X1 and X2-X2 of FIG. 2, in accordance with some embodiments of the disclosure.

FIG. 10B is a cross-sectional view of the semiconductor structure at an intermediate stage corresponding to lines X1-X1 and X2-X2 of FIG. 2, in accordance with some embodiments of the disclosure.

FIG. 10C is a cross-sectional view of the semiconductor structure at an intermediate stage corresponding to lines X1-X1 and X2-X2 of FIG. 2, in accordance with some embodiments of the disclosure.

FIG. 11 is a modification of the semiconductor structure of FIG. 3I-2, in accordance with some embodiments of the disclosure.

FIG. 12 is a modification of the semiconductor structure of FIG. 3I-1, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of a semiconductor structure are provided. The aspect of the present disclosure is directed to a semiconductor structure with a backside power rail architecture. The semiconductor structure includes cell regions with at least two different contact-poly pitches (CPP). The first cell region with a smaller contact-to-poly pitch has a shallower backside contact plug, while the second cell region with a large contact-to-poly pitch has a deeper backside contact plug. As a result, the first cell region may have the source/drain features with a greater volume to impart strain or stress to the channel region, while the second cell region may have a lower contact resistance and lower parasitic resistance. Therefore, the performance of the resulting semiconductor devices may be improved.

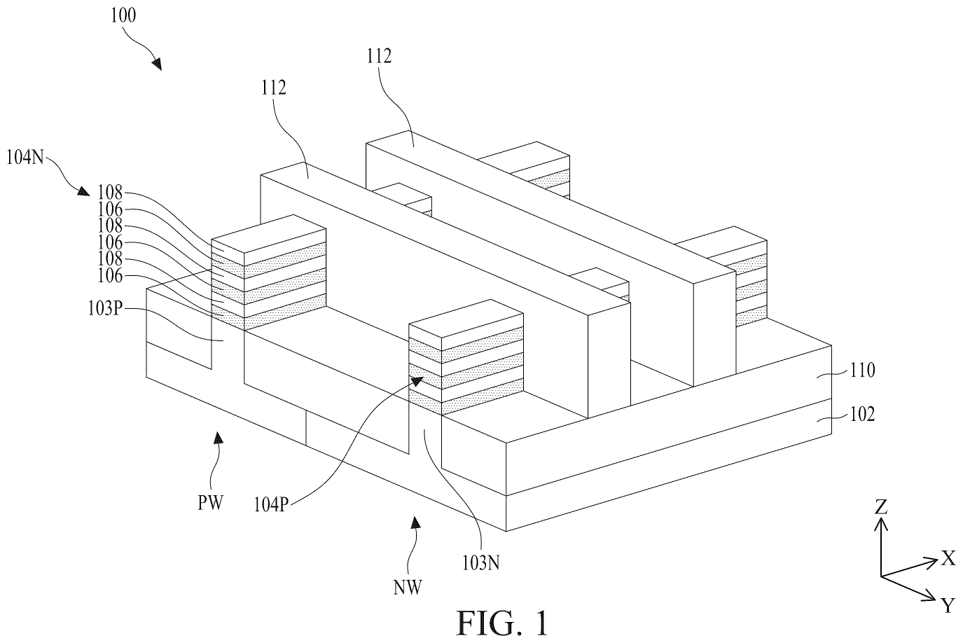

FIG. 1 Is a perspective view of a semiconductor structure 100, in accordance with some embodiments of the disclosure. The semiconductor structure 100 includes a substrate 102 and fin structures 104 (including 104N and 104P) over the substrate 102, as shown in FIG. 1, in accordance with some embodiments. The substrate 102 includes a p-type well PW and an n-type well NW immediately adjacent to the p-type well PW, in accordance with some embodiments. The fin structure 104N is formed in the p-type well PW of the substrate 102, and the fin structure 104P is formed in the n-type well NW of the substrate 102, in accordance with some embodiments. The fin structures 104N and 104P are the active regions of the semiconductor structure 100, in accordance with some embodiments.

For a better understanding of the semiconductor structure 100, the X-Y-Z coordinate reference is provided in the figures of the present disclosure. The X-axis and the Y-axis are generally orientated along the lateral (or horizontal) directions that are parallel to the main surface of the substrate 102. The Y-axis is transverse (e.g., substantially perpendicular) to the X-axis. The Z-axis is generally oriented along the vertical direction. The vertical direction is perpendicular to the main surface of the substrate 102 (or the X-Y plane).

The fin structure 104N includes a lower fin element 103P formed from the p-type well PW, and the fin structure 104P includes a lower fin element 103N formed from the n-type well NW, in accordance with some embodiments. The lower fin elements 103P and 103N are surrounded by an isolation structure 110, in accordance with some embodiments. Each of the fin structures 104N and 104P further includes an upper fin element formed from an epitaxial stack including alternating first semiconductor layers 106 and second semiconductor layer 108, in accordance with some embodiments. The second semiconductor layers 108 will form nanostructures (e.g., nanowires or nanosheets) and serve as the channel for the resulting semiconductor devices, in accordance with some embodiments.

The fin structures 104N and 104P extend in the X direction, in accordance with some embodiments. That is, the fin structures 104N and 104P have longitudinal axes parallel to the X direction, in accordance with some embodiments. The X direction may also be referred to as the channel-extending direction. The current of the resulting semiconductor device (i.e., nanostructure transistor) flows in the X direction through the channel. Each of the fin structures 104 is defined as several channel regions and several source/drain regions, where the channel regions and the source/drain regions are alternately arranged, in accordance with some embodiments. It is noted that in the present disclosure, source/drain region(s) or source/drain feature(s) may refer to a source or a drain, individually or collectively dependent upon the context.

Gate structures 112 are formed with longitudinal axes parallel to the Y direction and extending across and/or surrounding the channel regions of the fin structures 104N and 104P, in accordance with some embodiments. The source/drain regions of the fin structures 104N and 104P are exposed from the gate structures 112, in accordance with some embodiments. The Y direction may also be referred to as a gate-routing direction.

Although two fin structures 104 are illustrated in FIG. 1, the semiconductor structure 100 may include more than two fin structures 104. In addition, FIG. 1 shows two gate structures 112 (or channel regions) for illustrative purposes and is not intended to be limiting. The number of fin structures and the gate structures may be dependent on design demand of an integrated circuit and/or performance consideration of semiconductor devices.

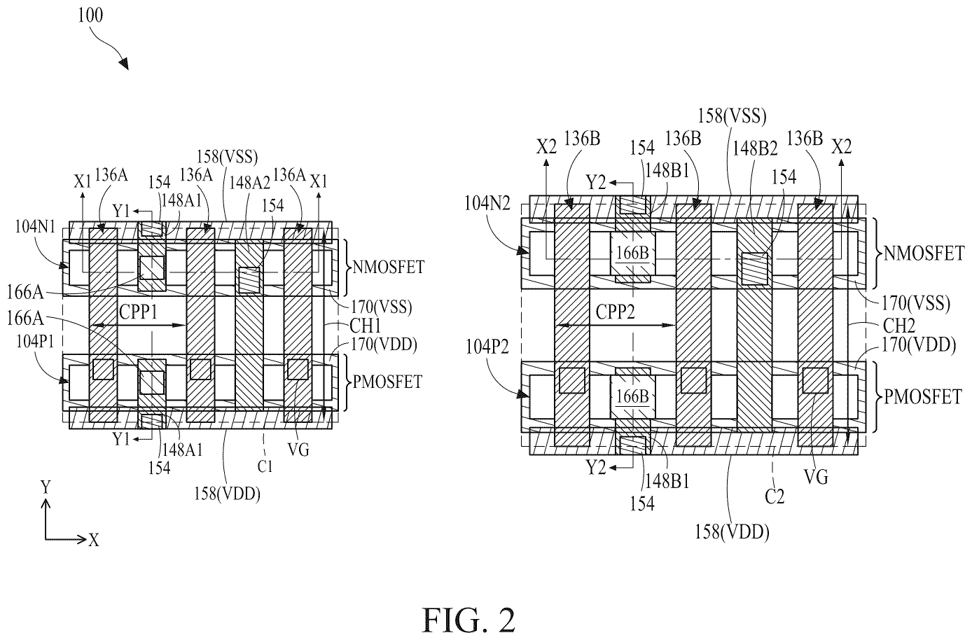

FIG. 2 illustrates a layout of a semiconductor structure 100 with a backside power rail architecture, in accordance with some embodiments. The semiconductor structure 100 is or includes nanostructure devices (e.g., GAA FETs), in accordance with some embodiments. The semiconductor structure 100 (or the substrate) is defined as or includes several cell regions, e.g., a first cell region C1 and a second cell region C2, in accordance with some embodiments. Functional circuits are formed in the respective cell regions and interconnected with each other to form integrated circuits, in accordance with some embodiments.

In some embodiments, the functional circuit in the first cell region C1 includes active regions 104N1 and 104P1 over a substrate (as shown in FIG. 1), final gate stacks 136A across the active regions 104N1 and 104P1, frontside contact plugs 148A (including 148A1 and 148A2), and backside contact plugs 166A. In some embodiments, the functional circuit in the second cell region C2 includes active regions 104N2 and 104P2 over the substrate, final gate stacks 136B across the active regions 104N2 and 104P2, frontside contact plugs 148B (including 148B1 and 148B2), and backside contact plugs 166B.

In some embodiments, the first cell region C1 has a smaller contact-poly pitch (CPP) CPP1 while the second cell region C2 has a greater contact-poly pitch CPP2 than the contact-poly pitch CPP1. The contact-poly pitch is the pitch of the final gate stacks or the frontside contact plugs, and may be defined as the sum of a dimension of the final gate stacks in the X direction and the spacing between the final gate stacks, or the dimension of the frontside contact plugs in the X direction and the spacing between the frontside contact plugs. In some embodiments, the contact-poly pitch CPP1 is in a range from about 30 nm to about 60 nm, and the contact-poly pitch CPP2 is in a range from about 45 nm to about 90 nm. In some embodiments, the functional circuit in the first cell region C1 may focus more on higher device energy efficiency, and the functional circuit in the second cell region C2 may focus more on higher performance (i.e., on-state current).

In some embodiments, the first cell region C1 is separate from the second cell region C2 by other cell regions. In some other embodiments, the first cell region C1 is immediately adjacent to the second cell region C2. In some embodiments, the first cell region C1 and the cell region C2 are STD cell regions (e.g., NAND, the inverter cell, NOR, AND, OR, Flip-Flop, and/or SCAN cell regions) or memory cell regions such as SRAM cell region. In some embodiments, the first cell region C1 has a smaller cell height CH1 while the second cell region C2 has a greater cell height CH2 than the cell height CH1 by about 10 nm to about 100 nm. In some other embodiments, the cell height CH1 of the first cell region C1 is substantially the equal to the cell height CH2 of the second cell region C2.

The active regions 104N (including 104N1 and 104N2) are located in the p-type wells (as shown in FIG. 1), and the active regions 104P (including 104P1 and 104P2) are located in the n-type wells (as shown in FIG. 1), in accordance with some embodiments. Each of the active regions 104N and 104P includes a lower fin element (103N or 103P as shown in FIG. 1) longitudinally oriented along the X direction and nanostructures (not shown in FIG. 2) formed over the lower elements, in accordance with some embodiments.

The final gate stacks 136A and 136B are longitudinally oriented along the Y direction and across the lower fin elements, and wrap around the nanostructures of the active regions 104N1 and 104P1 and the nanostructures of the active regions 104N2 and 104P2, in accordance with some embodiments. The final gate stacks 136A and 136B are combined with the nanostructures of the active regions 104N and 104P to form nanostructure transistors, in accordance with some embodiments. The nanostructure transistors are formed at the cross points between the active regions 104N and 104P and the final gate stacks 136A and 136B, in accordance with some embodiments. The nanostructure transistors which are formed on the active regions 104N1 and 104N2 (in the p-type wells) are n-channel nanostructure transistors NMOSFET, and the nanostructure transistors which are formed on the active regions 104P1 and 104P2 (in the n-type wells) are p-channel nanostructure transistors PMOSFET, in accordance with some embodiments.

The frontside contact plugs 148A and 148B (including 148A1, 148A2, 148B1 and 148B2) are formed on the source/drain regions of the active regions 104N and 104P, and electrically connected to the source or drain terminals of the nanostructure transistors, in accordance with some embodiments. The frontside contact plugs 148A1 and 148B1 are electrically connected to frontside power supply lines and may also serve as Vdd/Vss nodes of the functional circuits in the cell regions C1 and C2, in accordance with some embodiments. The contact plugs 148A2 and 148B2 are electrically connected to signal lines and may also serve as non-Vdd/Vss nodes of the functional circuits in the cell regions C1 and C2.

Vias 154 are formed on and electrically connected to the frontside contact plug 148A and 148B and may also be referred to as source/drain vias, while gate vias VG are formed on the final gate stacks 136A and 136B, in accordance with some embodiments.

A frontside metal layer (e.g., frontside first-level metal layer (F_M1)) is formed on and electrically connected to the vias 154 and the gate vias VG, in accordance with some embodiments. The frontside metal layer includes several conductive lines (tracks) e.g., power rails 158 and signal lines (not shown), in accordance with some embodiments. The power rails 158 include a Vdd frontside power rail providing positive voltage and a Vss frontside power rail which may be an electrical ground, in accordance with some embodiments. The signal lines are configured for signal transmission and are electrically isolated from the power supply lines, in accordance with some embodiments. The lines of the frontside metal layer are longitudinally oriented along the X direction, in accordance with some embodiments.

The Vss frontside power rails 158 are electrically connected to the Vss node (e.g., source terminals) of the n-channel nanostructure transistors NMOSFET through the vias 154 and the frontside contact plugs 148A1 and 148B1, in accordance with some embodiments. The Vdd frontside power rail 158 is electrically connected to the Vdd node (e.g., source terminals) of the p-channel nanostructure transistors PMOSFET through the vias 154 and the frontside contact plugs 148A1 and 148B1, in accordance with some embodiments.

The signal lines are electrically connected to the final gate stacks 136A and 136B through the gate vias VG, and to the non-Vdd/Vss nodes (e.g., drain terminals) of the nanostructure transistors NMOSFET and PMOSFET through the vias 154 and the contact plugs 148A2 and 148B2, in accordance with some embodiments.

Backside contact plugs 166A and 166B are formed under the source/drain regions of the active regions 104N and 104P, in accordance with some embodiments. The contact plugs 166A and 166B are electrically connected to the source terminals of the nanostructure transistors, in accordance with some embodiments. The backside contact plugs 166A and 166B are electrically connected to backside power supply lines and may also serve as Vdd/Vss nodes of the functional circuits in the cell regions C1 and C2, in accordance with some embodiments.

A backside metal layer (e.g., backside first-level metal layer (B_M1)) is formed under and electrically connected to the backside contact plugs 166A and 166B, in accordance with some embodiments. The backside metal layer includes several conductive lines (tracks) e.g., power rails 170, in accordance with some embodiments. In some embodiments, the backside metal layer includes no signal lines. In some other embodiments, the backside metal layer includes signal lines for signal transmission. The lines of the backside metal layer are longitudinally oriented along the X direction, in accordance with some embodiments. In some embodiments, the routing density (e.g., the number of tracks per unit area) of the backside metal layer (B_M1) is less than the routing density of the frontside metal layer (F_M1).

The Vss backside power rails 170 are electrically connected to the Vss node (e.g., source terminals) of the n-channel nanostructure transistors NMOSFET through the backside contact plugs 166A and 166B, in accordance with some embodiments. The Vdd backside power rails 170 are electrically connected to the Vdd node (e.g., source terminals) of the p-channel nanostructure transistors PMOSFET through the backside contact plugs 166A and 166B, in accordance with some embodiments. In some embodiments, the power rails are disposed on the dual sides of the semiconductor structure 100, which may reduce the total resistance of the metal layer. In some other embodiments, the frontside power rails 158 are omitted, thereby relaxing the metal routing density.

As the scale of the semiconductor devices continues to shrink, the scaling of metal layers in BEOL has been touched by the limitation on both resistance and capacitance due to increasingly smaller line width and line space. As a result, the performance improvement (e.g., increase in speed) of semiconductor devices (e.g., logic circuits) cannot rely solely on the device boosting, but also needs to concern about the RC delay of the metal conductors (e.g., metal lines) as well as IR voltage drop of the power supply (e.g., Vdd and Vss truly voltage position during operation for logic circuit). The backside power rail can provide a backend metal routing for the semiconductor devices on the backside of the substrate, thereby reducing the overall resistance (e.g., contact resistance and/or sheet resistance) of the BEOL metal layers, and/or reducing the complexity of the metal routing on the frontside of the substrate. Therefore, the backside power rail architecture may facilitate the continued scaling of semiconductor devices.

FIG. 2 further illustrates reference cross-sections that are used in later figures. Cross-section X1-X1 is in a plane parallel to the longitudinal axis (X direction) of the active region 104N1 and through the active region 104N1 of the first cell region C1, and cross-section X2-X2 is in a plane parallel to the longitudinal axis (X direction) of the active region 104N2 and through the active region 104N2 of the second cell region C2, in accordance with some embodiments. Cross-section Y1-Y1 is in a plane parallel to the longitudinal axis (Y direction) of the final gate stack 136A and across two Vdd/Vss nodes of the function circuit in the first cell region C1, and cross-section Y2-Y2 is in a plane parallel to the longitudinal axis (Y direction) of the final gate stack 136B and across two Vdd/Vss nodes of the function circuit in the second cell region C2, in accordance with some embodiments.

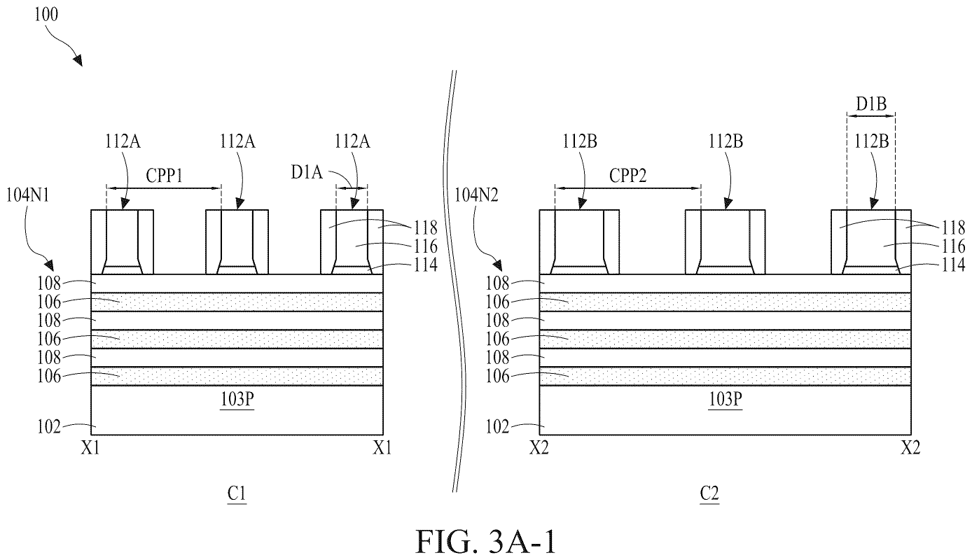

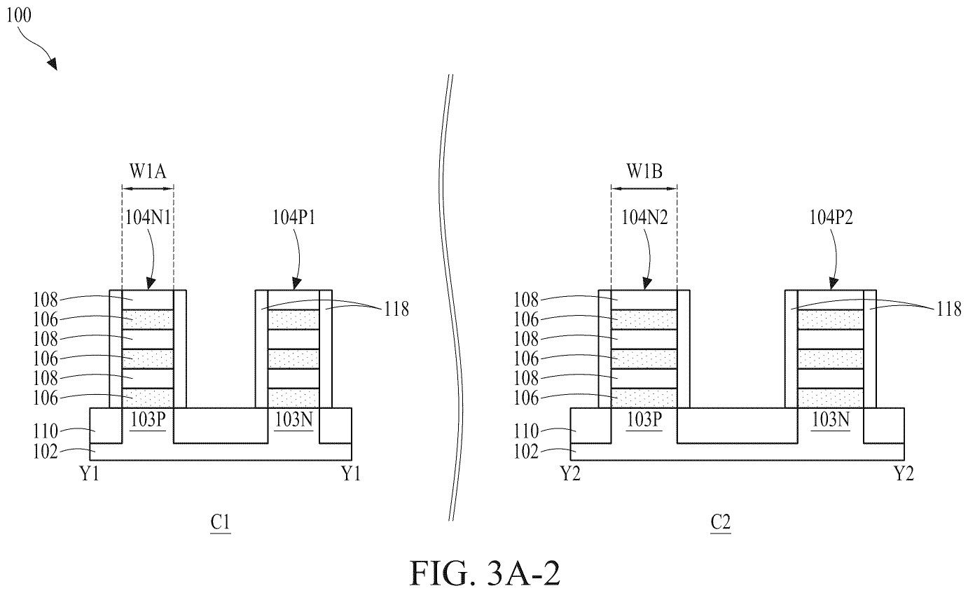

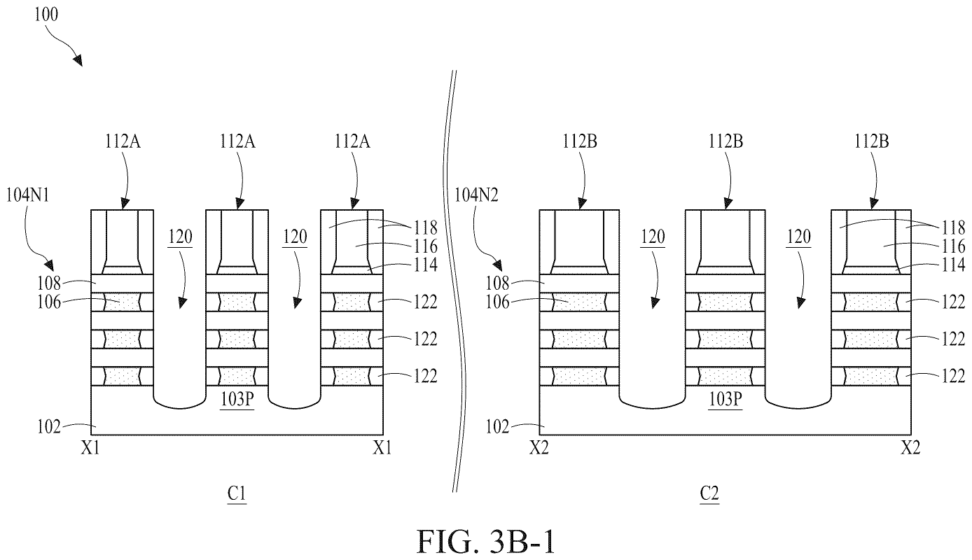

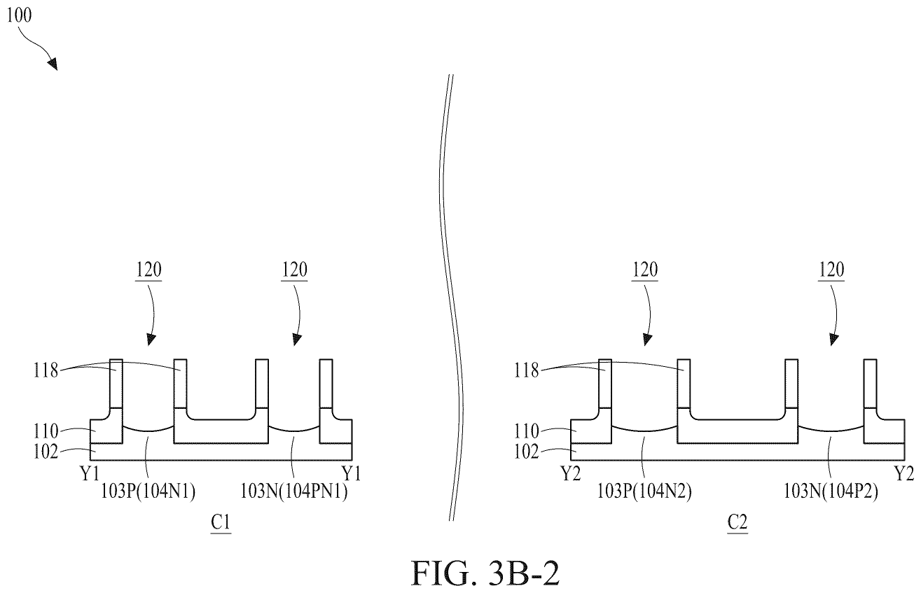

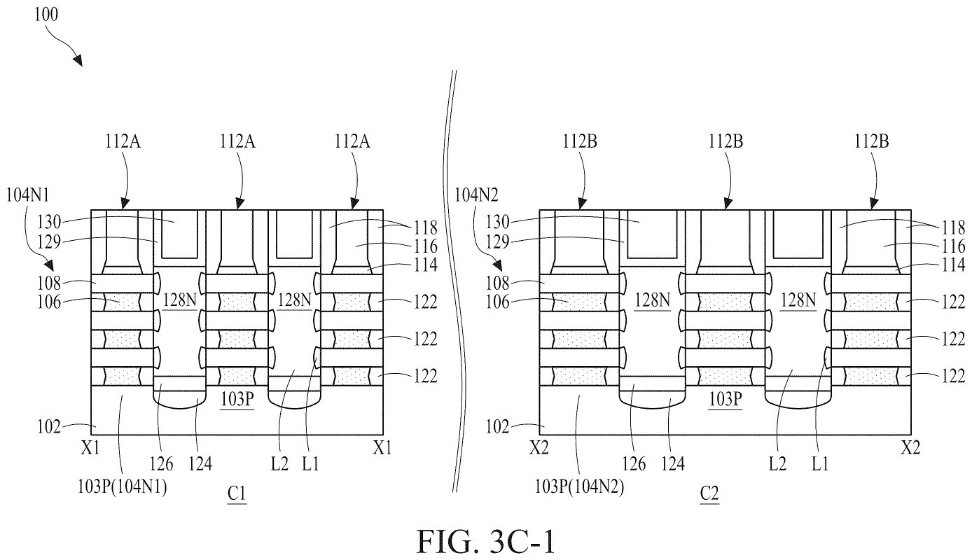

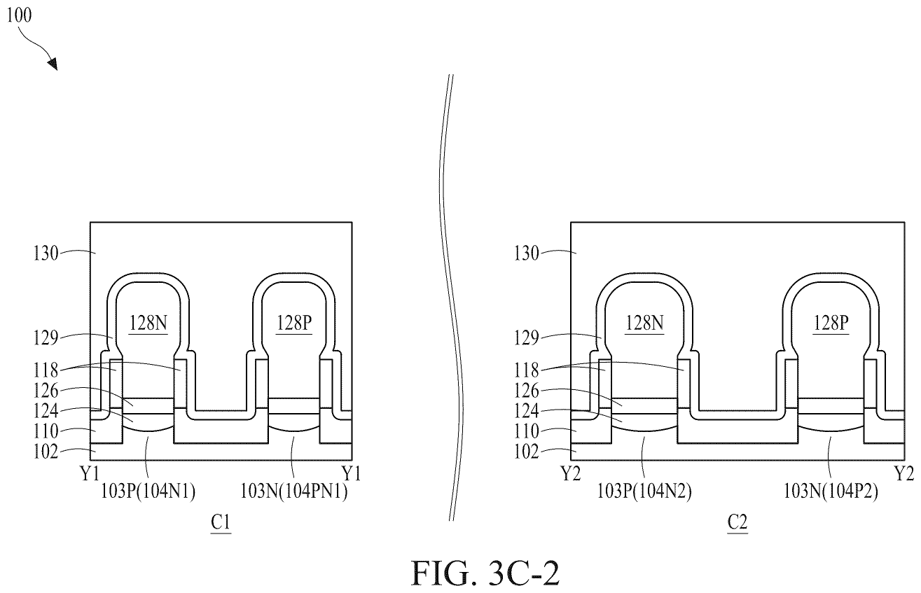

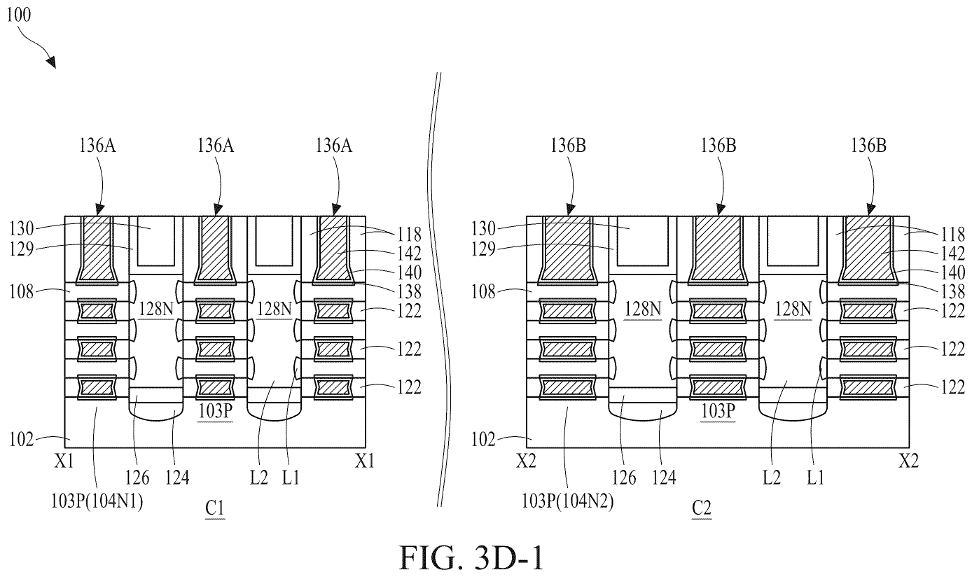

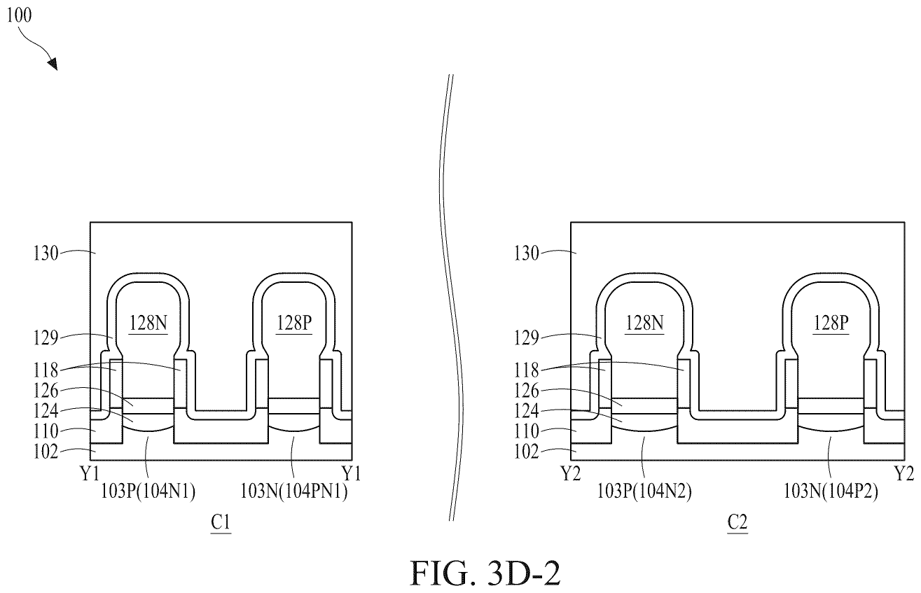

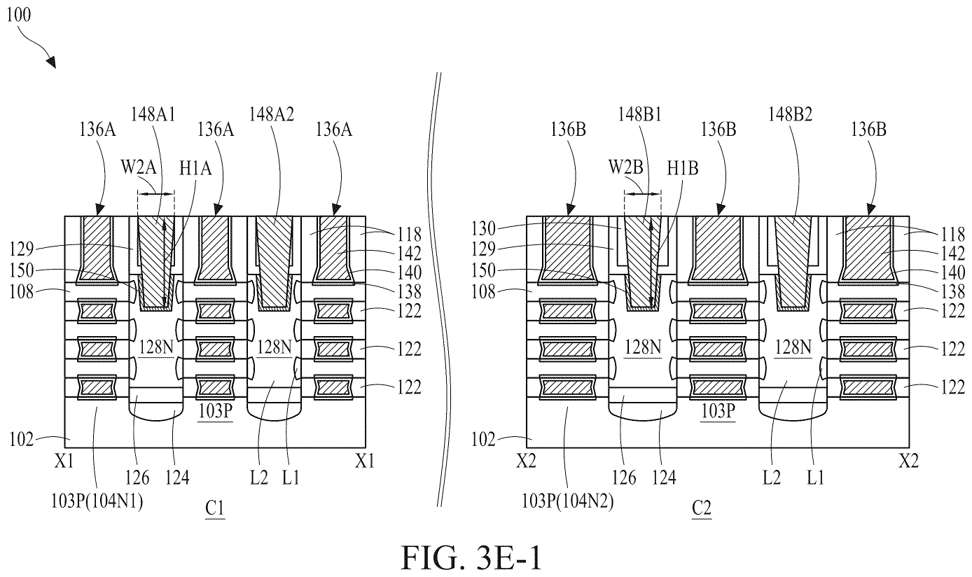

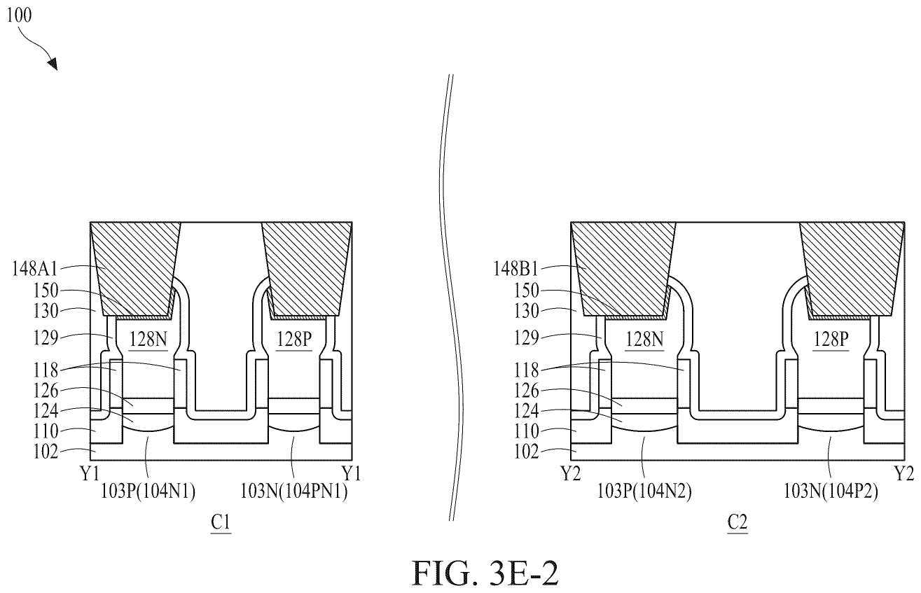

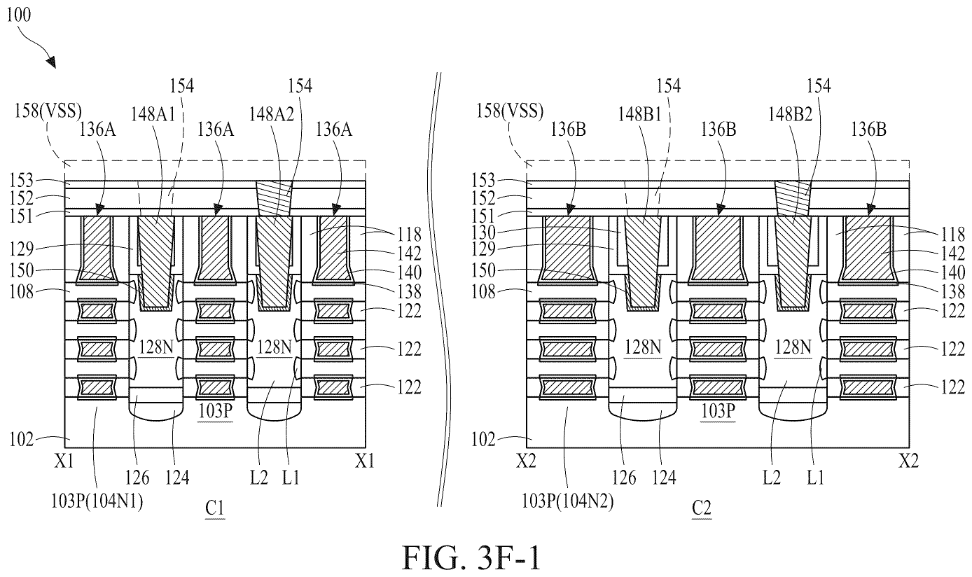

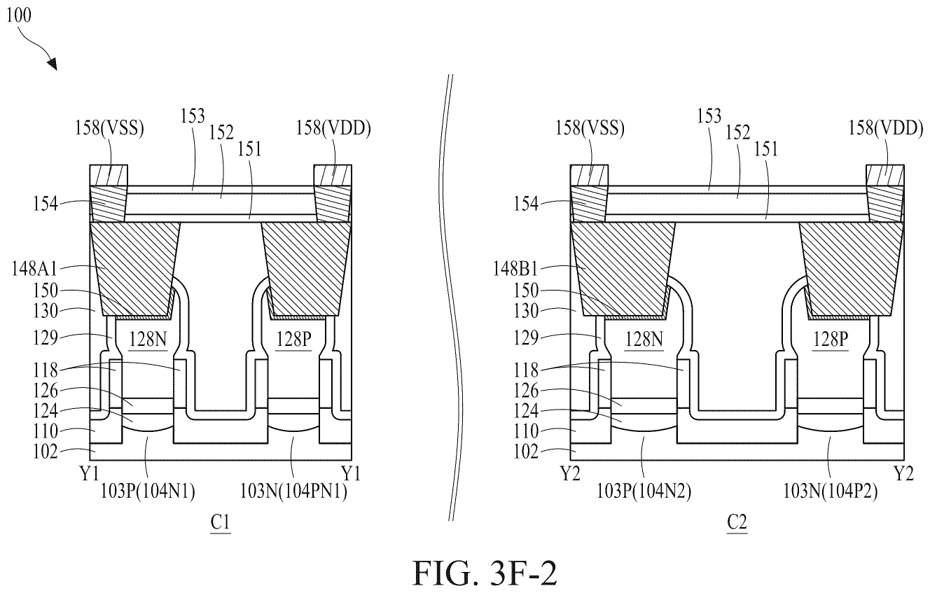

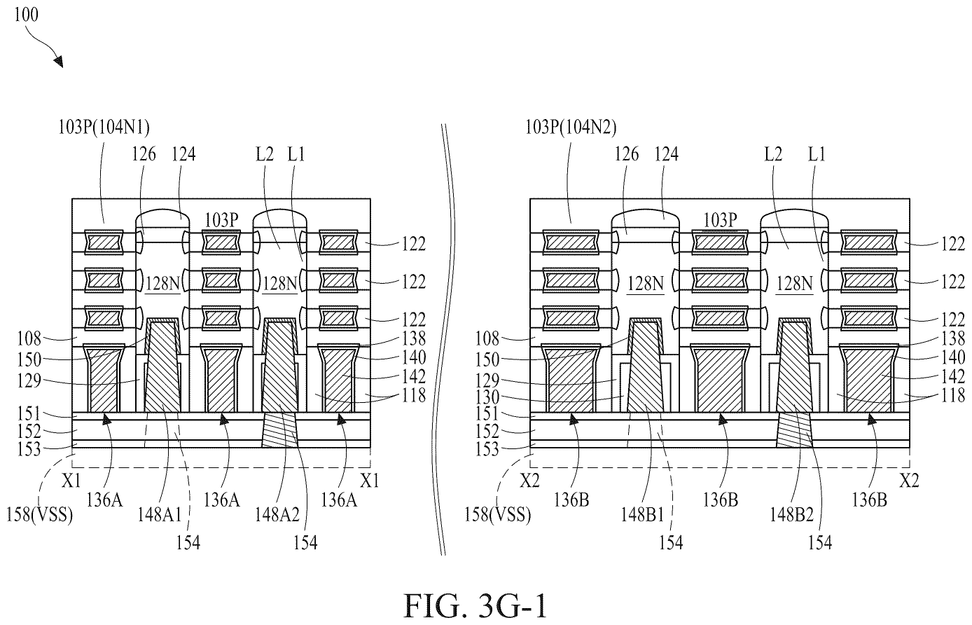

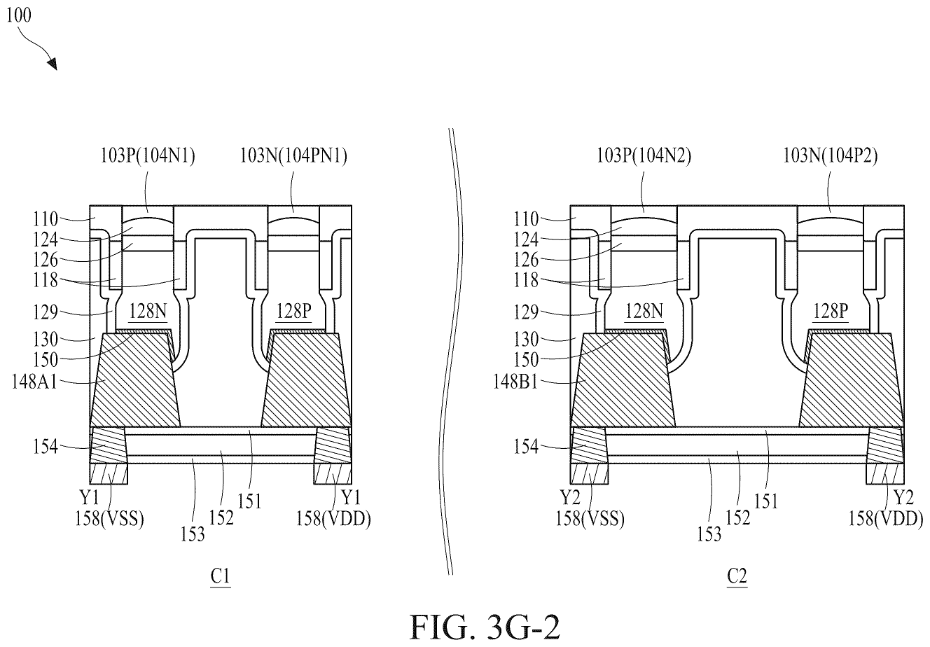

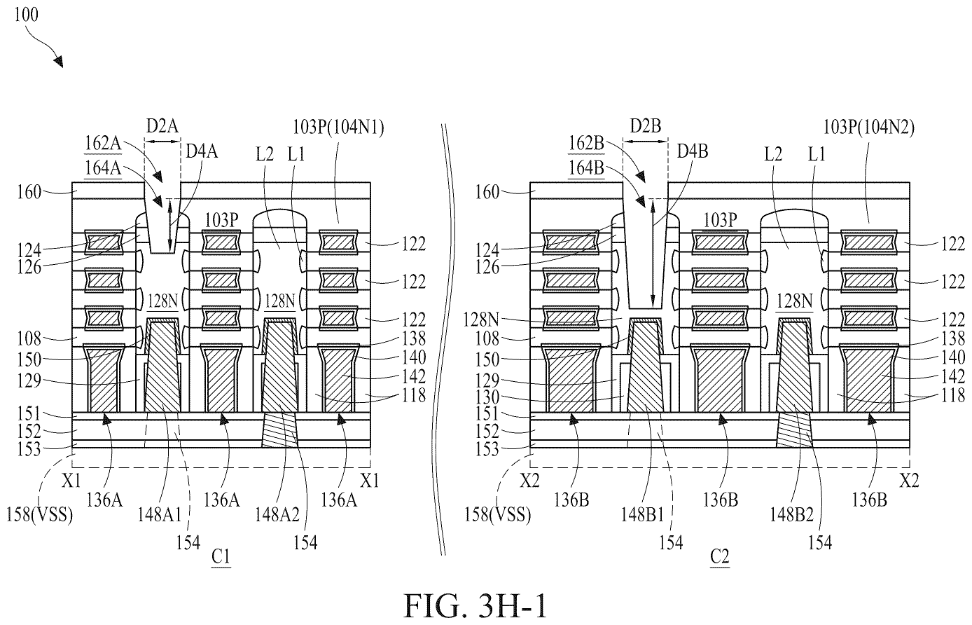

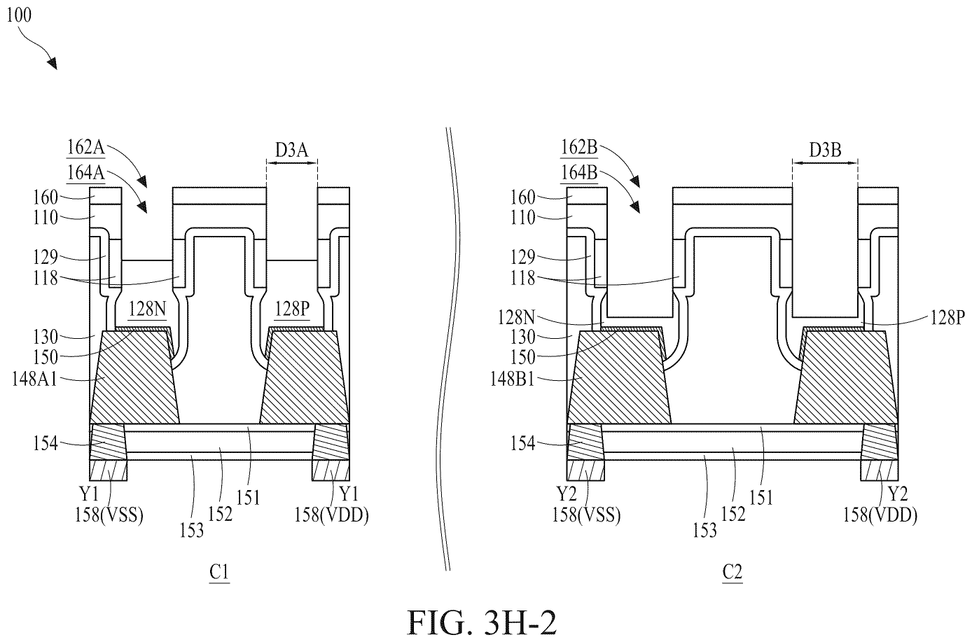

FIGS. 3A-1 through 3I-2 are cross-sectional views illustrating the formation of the semiconductor structure 100 of FIG. 2 at various intermediate stages, in accordance with some embodiments of the disclosure. FIGS. 3A-1, 3B-1, 3C-1, 3D-1, 3E-1, 3F-1, 3G-1, 3H-1 and 3I-1 correspond to lines X1-X1 and X2-X2 shown in FIG. 2. FIGS. 3A-2, 3B-2, 3C-2, 3D-2, 3E-2, 3F-2, 3G-2, 3H-2 and 3I-2 correspond to lines Y1-Y1 and Y2-Y2 shown in FIG. 2.

FIGS. 3A-1 and 3A-2 illustrate the semiconductor structure 100 after the formation of active regions 104N and 104P (including 104N1, 104N2, 104P1 and 104P2), an isolation structure 110, dummy gate structures 112A and 112B and spacer layers 118, in accordance with some embodiments.

A substrate 102 is provided, as shown in FIGS. 3A-1 and 3A-2, in accordance with some embodiments. The substrate 102 may be a portion of a semiconductor wafer, a semiconductor chip (or die), and the like. In some embodiments, the substrate 102 is a silicon substrate. The frontside surface of the substrate 102 (the frontside of the semiconductor structure 100) faces upward, in accordance with some embodiments.

In some embodiments, the substrate 102 includes an elementary semiconductor such as germanium; a compound semiconductor such as gallium nitride (GaN), silicon carbide (SiC), gallium arsenide (GaAs), gallium phosphide (GaP), indium phosphide (InP), indium arsenide (InAs), and/or indium antimonide (InSb); an alloy semiconductor such as SiGe, GaAsP, AlInAs, AlGaAs, GaInAs, GaInP, and/or GaInAsP; or a combination thereof. Furthermore, the substrate 102 may optionally include an epitaxial layer (epi-layer), may be strained for performance enhancement, may include a silicon-on-insulator (SOI) structure, and/or have other suitable enhancement features.

N-type dopants (such as phosphorus or arsenic) may be implanted into the substrate 102, thereby forming an n-type well (not shown), in accordance with some embodiments. P-type dopants (such as boron or BF₂) may be implanted into the substrate 102, thereby forming a p-type well (not shown), in accordance with some embodiments. In some embodiments, the respective concentrations of the dopants in the wells are in a range from about 10¹⁶/cm⁻³ to about 10¹⁸/cm⁻³. In some embodiments, the ion implantation processes may be performed several times with different dosages and different energy intensities. In some embodiments, the ion implantation process may include an anti-punch through (APT) implant.

Active regions 104N1, 104N2, 104P1 and 104P2 are formed over the substrate 102, as shown in FIGS. 3A-1 and 3A-2, in accordance with some embodiments. The active regions 104N1 and 104N2 are formed in the p-type wells, and the active regions 104P1 and 104P2 are formed in the n-type wells, in accordance with some embodiments. In some embodiments, the active regions 104N and 104P extend in the X direction.

The formation of the active regions 104N and 104P includes forming an epitaxial stack over the substrate 102 using an epitaxial growth process, in accordance with some embodiments. The epitaxial stack includes alternating first semiconductor layers 106 and second semiconductor layers 108, in accordance with some embodiments. The epitaxial growth process may be molecular beam epitaxy (MBE), metal organic chemical vapor deposition (MOCVD), or vapor phase epitaxy (VPE), or another suitable technique.

In some embodiments, the first semiconductor layers 106 are made of a first semiconductor material and the second semiconductor layers 108 are made of a second semiconductor material. The first semiconductor material for the first semiconductor layers 106 has a different lattice constant than the second semiconductor material for the second semiconductor layers 108, in accordance with some embodiments. In some embodiments, the first semiconductor material and the second semiconductor material have different oxidation rates and/or etching selectivity. In some embodiments, the first semiconductor layers 106 are made of SiGe, where the percentage of germanium (Ge) in the SiGe is in a range from about 20 atomic % to about 50 atomic %, and the second semiconductor layers 108 are made of pure or substantially pure silicon. In some embodiments, the first semiconductor layers 106 are Si₁₋ₓGeₓ, where x is more than about 0.3, or Ge (x=1.0) and the second semiconductor layers 108 are Si or Si_{1-y}Ge_{y}, where y is less than about 0.4, and x>y.

The first semiconductor layers 106 are configured as sacrificial layers and will be removed to form gaps to accommodate gate materials, and the second semiconductor layers 108 will form nanostructures (e.g., nanowires or nanosheets) that laterally extend between source/drain features and serve as the channel for the resulting semiconductor devices (such as nanostructure transistors), in accordance with some embodiments.

The formation of the active regions 104N and 104P further includes patterning the epitaxial stack and the underlying p-type and n-type wells using photolithography and etching processes, thereby forming trenches and the active regions 104N and 104P protruding from between trenches, in accordance with some embodiments. The portion of the p-type well protruding from between the trenches serves as a lower fin element 103P of the active region 104N, and the portion of the n-type well NW protruding from between the trenches serves as a lower fin element 103N of the active region 104P, in accordance with some embodiments. A remainder of the epitaxial stack (including the first semiconductor layers 106 and the second semiconductor layers 108) serves as the upper fin elements of the active regions 104N and 104P, in accordance with some embodiments. In some embodiments, the active regions 104N and 104P are the fin structures 104N and 104P as shown in FIG. 1.

In some embodiments, each of the first semiconductor layers 106 has a thickness in a range from about 6 nm to about 15 nm. In some embodiments, each of the second semiconductor layers 108 has a thickness in a range from about 4 nm to about 8 nm. The thickness of the second semiconductor layers 108 may be greater than, equal to, or less than the first semiconductor layers 106, depending on the amount of gate materials to be filled in spaces where the first semiconductor layers 106 are removed. Although three first semiconductor layers 106 and three second semiconductor layers 108 are shown in FIGS. 3A-1 and 3A-2, the number is not limited to three, and can be two or four, and is less than 10.

In some embodiments, the active regions 104N1 and 104P1 in the first cell region C1 have a width W1A (the dimension in the Y direction), and the active regions 104N2 and 104P2 in the second cell region C2 have a width W1B (the dimension in the Y direction), as shown in FIG. 3A-2. In some embodiments, the width W1B is greater than the width W1A by about 5 nm to about 40 nm. In some embodiments, the spacing between the active regions 104N1 and 104P1 is less than the spacing between the active regions 104N2 and 104P2.

An isolation structure 110 is formed to surround the lower fin elements 103P and 103N of the active regions 104N and 104P, as shown in FIG. 3A-2, in accordance with some embodiments. The isolation structure 110 is configured to electrically isolate the active regions 104N and 104P from each other and is also referred to as shallow trench isolation (STI) feature, in accordance with some embodiments. The formation of the isolation structure 110 includes forming an insulating material to overfill the trenches, in accordance with some embodiments. In some embodiments, the insulating material is made of silicon oxide (SiO₂), silicon nitride (SiN), silicon oxynitride (SiON), silicon carbide (SiC), oxygen-doped silicon carbide (SiC:O), oxygen-doped silicon carbonitride (Si(O)CN), or a combination thereof. In some embodiments, the insulating material is deposited using CVD (such as flowable CVD (FCVD), low-pressure CVD (LPCVD), plasma-enhanced CVD (PECVD), high density plasma CVD (HDP-CVD), or high aspect ratio process (HARP)), atomic layer deposition (ALD), another suitable technique, or a combination thereof.

A planarization process is performed on the insulating material to remove a portion of the insulating material above the active regions 104N and 104P, in accordance with some embodiments. The planarization may be chemical mechanical polishing (CMP), etching back process, or a combination thereof. The insulating material is then recessed using an etching process (such as dry plasma etching and/or wet chemical etching) until the upper fin elements of the active regions 104N and 104P are exposed, in accordance with some embodiments.

Dummy gate structures 112A and 112B are formed across the active regions 104N and 104P, as shown in FIG. 3A-1, in accordance with some embodiments. The dummy gate structures 112A and 112B are configured as sacrificial structures and will be replaced with the final gate stacks and the fin isolation structures, in accordance with some embodiments. In some embodiments, the dummy gate structures 112A and 112B extend in the Y direction. The dummy gate structures 112A and 112B surround the channel regions of the active regions 104N and 104P, in accordance with some embodiments. The dummy gate structures 112A and 112B may be similar to the gate structures 112 shown in FIG. 1.

Each of the dummy gate structures 112A and 112B includes a dummy gate dielectric layer 114 and a dummy gate electrode layer 116 over the dummy gate dielectric layer 114, in accordance with some embodiments. In some embodiments, the dummy gate dielectric layer 114 is conformally formed along the upper fin elements of the active regions 104. In some embodiments, the dummy gate dielectric layer 114 is made of one or more dielectric materials, such as silicon oxide (SiO), silicon nitride (SiN), silicon oxynitride (SiON), HfO₂, HfZrO, HfSiO, HfTiO, HfAlO. In some embodiments, the dielectric material is deposited using ALD, CVD, thermal oxidation, physical vapor deposition (PVD), another suitable technique, or a combination thereof.

In some embodiments, the material for the dummy gate electrode layer 116 is deposited using CVD, ALD, another suitable technique, or a combination thereof. Once the material for the dummy gate electrode layer 116 is deposited, the material for the dummy gate electrode layer 116 is planarized, and the material for the dummy gate electrode layer 116 and the dielectric material are patterned into the dummy gate structures 112A and 112B using photolithography and etching processes. In some embodiments, the portion of the dummy gate structures along the surfaces of the active region 104 are not so straight, and may have a footing profile (e.g., tailing portion) because of the characteristics of the etching process.

In some embodiments, the dummy gate structures 112A in the first cell region C1 has a dimension D1A in the X direction, and the dummy gate structures 112B in the second cell region C2 has a dimension D1B in the X direction, as shown in FIG. 3A-1. In some embodiments, the dimension D1B is greater than the dimension D1A. In some embodiments, the spacing between the dummy gate structures 112A is less than the spacing between the dummy gate structures 112B. In some embodiments, the contact-poly pitch CPP1 of the first cell region C1 is smaller than the contact-poly pitch CPP2 of the second cell region C2, as shown in FIG. 3A-1.

Spacer layers 118 are formed along the opposite sidewalls of the dummy gate structures 112A and 112B and the opposite sidewalls of the active regions 104N and 104P, as shown in FIGS. 3A-1 and 3A-2, in accordance with some embodiments. In some embodiments, the spacer layers 118 are made of a dielectric material, such as silicon nitride (SiN), silicon oxynitride (SiON), silicon oxide (SiO₂), oxygen-doped silicon carbide (SiC:O), oxygen-doped silicon carbonitride (Si(O)CN), silicon carbide (SiC), or another suitable dielectric material. In some embodiments, the formation of the spacer layers 118 includes globally and conformally dielectric material over the semiconductor structure 100A using ALD, CVD (such as LPCVD, PECVD or HDP-CVD or a combination thereof, followed by an anisotropic etching process, in accordance with some embodiments.

The vertical portions of the spacer layers 118 that are left remaining on the opposite sides of the dummy gate structures 112A and 112B may be referred to as gate spacer, and the vertical portions of the spacer layers 118 left on the opposite sides of the active regions 104N and 104P may be referred to as fin spacer. The gate spacer is used to offset the subsequently formed source/drain features and separate the source/drain features from the gate structure, in accordance with some embodiments. The fin spacer is used to constrain the lateral growth of subsequently formed source/drain features, in accordance with some embodiments.

FIGS. 3B-1 and 3B-2 illustrate the semiconductor structure 100 after the formation of source/drain recesses 120 and inner spacer layers 122, in accordance with some embodiments.

An etching process is performed to recess the source/drain regions of the active regions 104N and 104P, thereby forming source/drain recesses 120, as shown in FIGS. 3B-1 and 3B-2, in accordance with some embodiments. The etching process may be an anisotropic etching process such as dry plasma etching, an isotropic etching process such as dry chemical etching, remote plasma etching or wet chemical etching, or a combination thereof. The spacer layers 118 and the dummy gate structures 112A and 112B may serve as etch masks such that the source/drain recesses 120 are formed self-aligned on opposite sides of the dummy gate structures 112A and 112B, in accordance with some embodiments. The source/drain recesses 120 extend a distance into the lower fin elements 103N and 103P, in accordance with some embodiments. In some embodiments, the isolation structure 110 is also recessed.

An etching process is performed to laterally recess, from the source/drain recesses 120, the first semiconductor layers 106 of the active regions 104N and 104P, thereby forming notches, and then inner spacer layers 122 are formed in the notches, as shown in FIG. 3B-1, in accordance with some embodiments. The inner spacer layers 122 are formed to abut the recessed side surfaces of the first semiconductor layers 106, in accordance with some embodiments. In some embodiments, the inner spacer layers 122 are located between adjacent second semiconductor layers 108 and between the bottommost second semiconductor layer 108 and the lower fin element 103N (or 103P). The inner spacer layers 122 may avoid the source/drain features and the gate stack from being in direct contact and are configured to reduce the parasitic capacitance between the gate stack and the source/drain features (i.e., Cgs and Cgd), in accordance with some embodiments.

In some embodiments, the inner spacer layers 122 are made of a dielectric material, such as silicon oxide (SiO₂), silicon nitride (SiN), silicon carbide (SiC), silicon oxynitride (SiON), silicon carbon nitride (SiCN), silicon oxycarbonitride (SiOCN), oxygen-doped silicon carbonitride (Si(O)CN), a multilayer thereof, or a combination thereof. In some embodiments, the inner spacer layers 122 are formed by depositing a dielectric material for the inner spacer layers 122 over the semiconductor structure 100 to overfill the notches, and then etching back the dielectric material to remove the dielectric material outside the notches. In some embodiments, the deposition process includes ALD, CVD (such as PECVD, LPCVD or HARP), another suitable technique, or a combination thereof. In some embodiments, the etching back process includes an anisotropic etching process such as dry plasma etching, an isotropic etching process such as dry chemical etching, remote plasma etching or wet chemical etching, or a combination thereof.

FIGS. 3C-1 and 3C-2 illustrate the semiconductor structure 100 after the formation of semiconductor isolation layers 124, dielectric isolation layers 126, source/drain features 128N and 128P (including 128N and 128P), a contact etching stop layer 129 and a first interlayer dielectric layer 130, in accordance with some embodiments.

Semiconductor isolation layers 124 are grown on the lower fin elements 103N and 103P, as shown in FIGS. 3C-1 and 3C-2, in accordance with some embodiments. In some embodiments, the semiconductor isolation layers 124 are made of an epitaxial semiconductor material such as silicon, silicon germanium or germanium, formed by MBE, MOCVD, or VPE, another suitable technique, or a combination thereof. In an embodiment, the semiconductor isolation layers 124 are made of non-doped silicon.

Dielectric isolation layers 126 are optionally formed on the semiconductor isolation layers 124, as shown in FIGS. 3C-1 and 3C-2, in accordance with some embodiments. In some embodiments, the dielectric isolation layers 126 are made of dielectric material silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O)CN). In some embodiments, the dielectric isolation layers 126 are formed a deposition process followed by and an etching-back process.

In some embodiments, the sidewalls of the bottommost second semiconductor layers 108 are uncovered by the dielectric isolation layers 126. The semiconductor isolation layers 124 and the dielectric isolation layers 126 may be configured to reduce the total cell capacitance, in accordance with some embodiments.

Source/drain features 128N and 128P are formed on the exposed sidewalls of the second semiconductor layers 108 using one or more epitaxial growth processes, as shown in FIGS. 3C-1 and 3C-2, in accordance with some embodiments. These epitaxial growth processes may be MBE, MOCVD, or VPE, another suitable technique, or a combination thereof. The source/drain features 128N and 128P are located on the dielectric isolation layers 126 in the source/drain recesses 120, in accordance with some embodiments. The source/drain features 128N and 128P are located on opposite sides of the dummy gate structures 112A and 112B, in accordance with some embodiments. In some embodiments, the source/drain features 128N have a different electrically conductive type than the source/drain features 128P.

In some embodiments, the source/drain features 128N and the source/drain features 128P may be formed separately. For example, a patterned mask layer (such as a photoresist layer and/or a hard mask layer) may be formed to cover the semiconductor structure 100 over the n-type wells, and then the source/drain features 128N are grown. Afterward, the patterned mask layer may be removed. Similarly, a patterned mask layer (such as a photoresist layer and/or a hard mask layer) is formed to cover the semiconductor structure 100 over the p-type wells, and then the source/drain features 128P are grown. Afterward, the patterned mask layer may be removed. In some embodiments, the source/drain features 128N and 128P are in-situ doped during the epitaxial processes.

In some embodiments, the source/drain features 128N are doped with the n-type dopant during the epitaxial growth process. For example, the n-type dopant may be phosphorous (P) or arsenic (As). For example, the n-type source/drain features 128N may be the epitaxially grown silicon phosphorous (SiP), silicon carbon (SiC), silicon phosphorous carbon (SiPC), silicon phosphorous arsenic (SiPAs), silicon arsenic (SiAs), silicon (Si), or a combination thereof doped with phosphorous and/or arsenic.

In some embodiments, the source/drain features 128P are doped with the p-type dopant during the epitaxial growth process. For example, the p-type dopant may be boron (B) or BF₂. For example, the p-type source/drain features 128P may be the epitaxially grown silicon germanium (SiGe), silicon germanium carbon (SiGeC), germanium (Ge), silicon (P), or a combination thereof doped with boron (B).

In some embodiments, each of the source/drain features 128N and 128P may be multilayered structures, e.g., including epitaxial barrier layers L1 formed on the sidewalls of the second semiconductor layers, and an epitaxial bulk layer L2 then filling remaining portions of the source/drain recesses 120, as shown in FIG. 3C-1. In some embodiments, the concentration of the dopant in the bulk layer L2 is higher than the concentration of the dopant in the barrier layers L1, e.g., by 1-2 orders. In some embodiments, the concentrations of the dopant (e.g., P) in the bulk layer L2 of the source/drain features 128N are in a range from about 2×10¹⁹ cm⁻³ to about 3×10²¹ cm⁻³ . In some embodiments, the concentrations of the dopant (e.g., B) in the bulk layer L2 of the source/drain features 128P are in a range from about 1×10¹⁹ cm⁻³ to about 6×10²⁰ cm⁻³.

In some embodiments, the n-type source/drain features 128N and the p-type source/drain features 128P are made of different epitaxial materials. For example, the n-type source/drain features 128N are made of SiP, and the p-type source/drain features 128P are made of SiGe. In some embodiments, in the X direction, the dimension of the source/drain features 128N and 128P in the first cell region C1 is less than the dimension of the source/drain features 128N and 128P in the second cell region C2 by about 1 nm to about 10 nm. In some embodiments, in the Y direction, the dimension of the source/drain features 128N and 128P in the first cell region C1 is less than the dimension of the source/drain features 128N and 128P in the second cell region C2 by about 5 nm to about 40 nm.

A contact etching stop layer 129 is formed over the semiconductor structure 100 to cover the source/drain features 128N and 128P, as shown in FIGS. 3C-1 and 3C-2, in accordance with some embodiments. In some embodiments, the contact etching stop layer 129 is made of a dielectric material, such as silicon nitride (SiN), silicon oxynitride (SiON), silicon oxide (SiO₂), oxygen-doped silicon carbide (SiC:O), oxygen-doped silicon carbonitride (Si(O)CN), silicon carbide (SiC), or another suitable dielectric material. In some embodiments, the contact etching stop layer 129 is globally and conformally deposited using ALD, CVD (such as LPCVD, PECVD, HDP-CVD and HARP), another suitable method, and/or a combination thereof.

A first interlayer dielectric layer 130 is formed over the contact etching stop layer 129, as shown in FIGS. 3C-1 and 3C-2, in accordance with some embodiments. The first interlayer dielectric layer 130 overfills the space between dummy gate structures 112A and 112B, in accordance with some embodiments. In some embodiments, the first interlayer dielectric layer 130 is made of dielectric material, such as un-doped silicate glass (USG), doped silicon oxide such as borophosphosilicate glass (BPSG), fluoride-doped silicate glass (FSG), phosphosilicate glass (PSG), borosilicate glass (BSG), or another suitable dielectric material. In some embodiments, the dielectric material for the first interlayer dielectric layer 130 is deposited using such as CVD (such as HDP-CVD, PECVD, HARP or FCVD), another suitable technique, or a combination thereof. The dielectric materials for the contact etching stop layer 129 and the first interlayer dielectric layer 130 above the top surface of the dummy gate electrode layer 116 are removed using such as CMP, in accordance with some embodiments.

FIGS. 3D-1 and 3D-2 illustrate cross-sectional views of the semiconductor structure 100 after the formation of final gate stacks 136A and 136B, in accordance with some embodiments.

One or more etching processes are performed to remove the dummy gate structures 112A and 112B to form gate trenches, and remove the first semiconductor layers 106 of the active regions 104N and 104P to form gaps, in accordance with some embodiments. In some embodiments, the gate trenches expose the channel regions of the active regions 104N and 104P. In some embodiments, the gate trenches further expose the sidewalls of the gate spacers facing the channel region. In some embodiments, the gaps expose the sidewalls of the inner spacer layers 122 facing the channel region. The one or more etching processes may include an anisotropic etching process such as dry plasma etching, an isotropic etching process such as dry chemical etching, remote plasma etching or wet chemical etching, or a combination thereof.

After the one or more etching processes, the four main surfaces of the second semiconductor layers 108 are exposed, in accordance with some embodiments. The exposed second semiconductor layers 108 form sets of nanostructures 108, in accordance with some embodiments. Each set includes three nanostructures 108 vertically stacked and spaced apart from one other, in accordance with some embodiments. As the term is used herein, “nanostructures” refers to the semiconductor layers with cylindrical shape, bar shaped and/or sheet shape. The nanostructures 108 function as channels of the resulting semiconductor devices (e.g., nanostructure transistors such as GAA transistors), in accordance with some embodiments.

Final gate stacks 136A and 136B are formed in the gate trenches and gaps, thereby wrapping around the nanostructures 108, as shown in FIG. 3D-1, in accordance with some embodiments. In some embodiments, the final gate stacks 136A and 136B extend in the Y direction. The final gate stacks 136A and 136B engage the channel region so that current can flow between the source/drain regions during operation.

In some embodiments, the dimension of the final gate stack 136B in the X direction (substantially equal to the dimension D1B) is greater than the dimension of the final gate stack 136A in the X direction (substantially equal to the dimension D1A). In some embodiments, the spacing between the final gate stacks 136A in the first cell region C1 is less than the spacing between the final gate stacks 136B in the second cell region C2.

In some embodiments, each of the final gate stacks 136A and 136B includes an interfacial layer 138, a gate dielectric layer 140 and a metal gate electrode layer 142, as shown in FIG. 3D-1, in accordance with some embodiments. The interfacial layer 138 is formed on the exposed surfaces of the nanostructures 108 and the exposed surfaces of the lower fin elements 103N and 103P, in accordance with some embodiments. The interfacial layer 138 wraps around the nanostructures 108, in accordance with some embodiments.

In some embodiments, the interfacial layer 138 is made of a chemically formed silicon oxide. In some embodiments, the interfacial layer 138 is nitrogen-doped silicon oxide. In some embodiments, the interfacial layer 138 is formed using one or more cleaning processes such as including ozone (O₃), ammonia hydroxide-hydrogen peroxide-water mixture, and/or hydrochloric acid-hydrogen peroxide-water mixture. Semiconductor material from the nanostructures 108 and the lower fin elements 103N and 103P is oxidized to form the interfacial layer 138, in accordance with some embodiments.

The gate dielectric layer 140 is formed conformally along the interfacial layer 138 to wrap around the nanostructures 108, in accordance with some embodiments. The gate dielectric layer 140 is further formed along the exposed sidewalls of the spacer layers 118 and the inner spacer layers 122 facing the channel region, in accordance with some embodiments. The gate dielectric layer 140 may be a high-k dielectric layer. In some embodiments, the high-k dielectric layer is dielectric material with a high dielectric constant (k value), for example, greater than 9, such as greater than 13. In some embodiments, the high-k dielectric layer includes hafnium oxide (HfO₂), TiO₂, HfZrO, Ta₂O₃, HfSiO₄, ZrO₂, ZrSiO₂, LaO, Al₂O₃, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Si₃N₄, oxynitrides (SiON), a combination thereof, or another suitable material. The high-k dielectric layer may be deposited using ALD, PVD, CVD, or another suitable technique.

The metal gate electrode layer 142 is formed over the gate dielectric layer 140 and overfills the remainder of the gate trench and the gaps, in accordance with some embodiments. In some embodiments, the metal gate electrode layer 142 is made of more than one conductive material, such as a metal, metal alloy, conductive metal oxide and/or metal nitride, another suitable conductive material, or a combination thereof. For example, the metal gate electrode layer 142 may be made of Ti, Ag, Al, TiAlN, TaC, TaCN, TaSiN, Mn, Zr, TiN, TaN, Ru, Mo, WN, Cu, W, Re, Ir, Co, Ni, Pt, another suitable conductive material, or multilayers thereof. The metal gate electrode layer 142 may be a multi-layer structure with various combinations of a diffusion barrier layer, work function layers with a selected work function to enhance the device performance for n-channel FETs or p-channel FETs, a capping layer to prevent oxidation of work function layers, a glue layer to adhere work function layers to the next layer, and a metal fill layer to reduce the total resistance of gate stacks, or another suitable layer.

A planarization process such as CMP may be performed on the semiconductor structure 100 to remove the materials of the gate dielectric layer 140 and the metal gate electrode layer 142 formed above the upper surface of the first interlayer dielectric layer 130, in accordance with some embodiments. The final gate stacks 136A and 136B that are wrapped around the nanostructures 108 combine with the neighboring source/drain features 128N or 128P to form nanostructure transistors. In some embodiments, the transistors formed on the nanostructures 108 in the p-type well are the n-channel nanostructure transistors (NMOSFET in FIG. 2), and the transistors formed on the nanostructures 108 in the n-type well are the p-channel nanostructure transistors (PMOSFET in FIG. 2).

FIGS. 3E-1 and 3E-2 illustrate the semiconductor structure 100 after the formation of frontside contact plugs 148A (including 148A1 and 148A2), and 148B (including 148B1 and 148B2), in accordance with some embodiments.

Frontside contact plugs 148A and 148B are formed in or through the first interlayer dielectric layer 130 and the contact etching stop layer 129 to land on the source/drain features 128N and 128P, as shown in FIGS. 3E-1 and 3E-2, in accordance with some embodiments. The contact plugs 148A1 and 148B1 are electrically connected to subsequently formed power supply lines and may also serve as Vdd/Vss nodes, in accordance with some embodiments. The contact plugs 148B1 and 148B2 are electrically connected to subsequently formed signal lines and may also serve as non-Vdd/Vss nodes. In some embodiments, the contact plugs 148A and 148B extend in the Y direction.

In some embodiments, the formation of the contact plugs 148A and 148B includes patterning the first interlayer dielectric layer 130, the contact etching stop layer 129 and the underlying source/drain features 128N and 129P to form contact openings (where the contact plugs 148A and 148B are to be formed) using photolithography and etching processes. The etch process may include dry etching such as RIE, NBE, ICP etch, CPP etch, another suitable method, or a combination thereof.

The contact plugs 148A and 148B may have a multilayer structure. For example, silicide layers 150 are formed on the exposed surfaces of the source/drain features 128N and 128P. In some embodiments, the silicide layers 150 are made of WSi, NiSi, TiSi and/or CoSi. In some embodiments, the formation of the silicide layers 150 includes depositing a metal material followed by one or more annealing processes. The semiconductive material (e.g., Si or SiGe) from the source/drain features 128N and 128P reacts with the metal material to form the silicide layers 150, in accordance with some embodiments, The unreacted metal material is then removed using a cleaning process.

One or more conductive materials are deposited on the silicide layers 150 to overfill the contact openings, in accordance with some embodiments. For example, one or more conductive materials include a barrier/adhesive layer and a metal bulk layer on the barrier/adhesive layer. In some embodiments, the barrier/adhesive layer may be made of tantalum (Ta), tantalum nitride (TaN), titanium (Ti), titanium nitride (TiN), cobalt tungsten (CoW), another suitable material, or a combination thereof. In some embodiments, the metal bulk layer is made of one or more conductive materials with low resistance and good gap-fill ability, for example, cobalt (Co), nickel (Ni), tungsten (W), titanium (Ti), tantalum (Ta), copper (Cu), rhodium (Rh), iridium (Ir), platinum (Pt), aluminum (Al), ruthenium (Ru), molybdenum (Mo), another suitable metal material, or a combination thereof.

In some embodiments, one or more conductive materials are deposited using CVD, PVD, e-beam evaporation, ALD, electroplating (ECP), electroless deposition (ELD), another suitable method, or a combination thereof to overfill the contact openings. In some embodiments, the metal bulk layer is formed using a selective deposition technique such as cyclic CVD process or ELD process, and it is not necessary to form the barrier/adhesive layer before depositing the metal bulk material. The one or more conductive materials over the upper surface of the first interlayer dielectric layer 130 are planarized using, for example, CMP.

In some embodiments, the contact plugs 148A and 148B have downward tapering sidewalls. The bottom surfaces of the silicide layers 150 of the contact plugs 148A and 148B are located at a position that is substantially level with or lower than the bottom surface of the topmost nanostructures 108, as shown in FIG. 3E-1, in accordance with some embodiments. A deeper extension of the contact plugs may reduce the parasitic resistance (Rp) of the resulting semiconductor device, in accordance with some embodiments. In some embodiments, the bottom surfaces of the silicide layers 150 are not lower than the top surfaces of the second topmost nanostructures 108.

In some embodiments, the silicide layers 150 of the contact plugs 148A and 148B are in direct contact with the epitaxial bulk layer L2 of the source/drain features 128N and 128P, but separate from the epitaxial barrier layers L1 of the source/drain features 128N and 128P. Due to the low dopant concentration of the barrier layers L1, the contact between the silicide layers 150 and the barrier layers L1 may increase the contact resistance.

In some embodiments, the contact plugs 148A1 and 148A2 in the first cell region C1 has a width W2A (the dimension in the X direction) and a height H1A (the dimension in the Z direction), and the contact plugs 148B1 and 148B2 in the second cell region C2 has a width W2B (the dimension in the X direction) and a height H1B (the dimension in the Z direction). In some embodiments, the width W2A is substantially equal to the width W2B, and the height H1A is substantially equal to the height H1B. In some other embodiments, the width W2B is greater than the width W2A, and the height H1B is greater than the height H1A.

FIGS. 3F-1 and 3F-2 illustrate the semiconductor structure 100 after the formation of an etching stop layer 151, a second interlayer dielectric layer 152, a dielectric cap layer 153, vias 154, and a power rail 158, in accordance with some embodiments.

An etching stop layer 151, a second interlayer dielectric layer 152 and a dielectric cap layer 153 are subsequentially formed on the semiconductor structure 100, as shown in FIGS. 3F-1 and 3F-2, in accordance with some embodiments. In some embodiments, the second etching stop layer 151 and the dielectric cap layer 153 are made of dielectric material, such as silicon nitride (SiN), silicon oxide (SiO₂), silicon oxynitride (SiON), silicon carbide (SiC), oxygen-doped silicon carbide (SiC:O), oxygen-doped silicon carbonitride (Si(O)CN), or a combination thereof. In some embodiments, the second interlayer dielectric layer 152 is made of dielectric material, such as USG, BPSG, FSG, PSG, BSG, or another suitable dielectric material. In some embodiments, the etching stop layer 151, the second interlayer dielectric layer 152 and the dielectric cap layer 153 are deposited using CVD (such as HDP-CVD, PECVD, HARP or FCVD), another suitable technique, or a combination thereof.

Vias 154 are formed in or through the dielectric cap layer 153, the second interlayer dielectric layer 152 and the etching stop layer 151 and land on the contact plugs 148A and 148B, as shown in FIGS. 3F-1 to 3F-2, in accordance with some embodiments. Two vias 154 are shown as dash lines in FIG. 3F-1, which indicates that they are not in the cross-sectional view. Although not shown, gate vias (e.g., VG in FIG. 2) are formed in or through the dielectric cap layer 153, the second interlayer dielectric layer 152 and the etching stop layer 151 and land on the final gate stacks 136A and 136B.

In some embodiments, the formation of the vias 154 includes patterning the dielectric cap layer 153, the second interlayer dielectric layer 152 and the etching stop layer 151 to form via openings (where the vias 154 are to be formed) using photolithography and etching processes. The etch processes may include dry etching such as RIE, NBE, ICP etch, CPP etch, another suitable method, or a combination thereof. Afterward, one or more conductive materials are deposited using CVD, PVD, e-beam evaporation, ALD, ECP, ELD, another suitable method, or a combination thereof to overfill the via openings, in accordance with some embodiments. The one or more conductive materials over the upper surface of the dielectric cap layer 153 are planarized using, for example, CMP.

The vias 154 may have a multilayer structure. For example, a barrier/adhesive layer (not shown) may optionally be deposited along the sidewalls and the bottom surfaces of the via openings. The barrier layer may be made of tantalum (Ta), tantalum nitride (TaN), titanium (Ti), titanium nitride (TiN), cobalt tungsten (CoW), another suitable material, or a combination thereof. A metal bulk layer is then deposited on the barrier/adhesive layer (if formed) to fill the remainder of the via openings. In some embodiments, the metal bulk layers are made of one or more conductive materials, such as cobalt (Co), nickel (Ni), tungsten (W), titanium (Ti), tantalum (Ta), copper (Cu), rhodium (Rh), iridium (Ir), platinum (Pt), aluminum (Al), ruthenium (Ru), molybdenum (Mo), or a combination thereof.

In some embodiments, the dimension (in the X direction or Y direction) of the vias 154 in the second cell region C2 are substantially the same as the dimension (in the X direction or Y direction) of the vias 154 in the first cell region C1. In some other embodiments, the dimension of the vias 154 in the second cell region C2 may be greater than dimension of the vias 154 in the first cell region C1 by about 1 nm to about 10 nm.

An intermetal dielectric layer (not shown) is formed over semiconductor structure 100, and a frontside first metal layer (F_M1) is formed in or through the intermetal dielectric layer, in accordance with some embodiments. The frontside first metal layer includes several lines (tracks) e.g., power rails 158 and signal lines (not shown), as shown in FIGS. 3F-1 and 3F-2, in accordance with some embodiments. Two power rails 158 are shown as dash lines in FIG. 3F-1, which indicates that they are not in the cross-sectional view.

The Vss power rail 158 is electrically connected to the Vss node (e.g., source terminals) of the n-channel nanostructure transistors through the vias 154 and the contact plugs 148A1 and 148B1, in accordance with some embodiments. The Vdd power rail is electrically connected to the Vdd node (e.g., source terminals) of the p-channel nanostructure transistors through the vias 154 and the contact plugs 148A1 and 148B1, in accordance with some embodiments. The signal lines are electrically connected to the final gate stacks 136A and 136B through the gate vias VG, and electrically connected to the non-Vdd/Vss nodes (e.g., drain terminals) of the n-channel nanostructure transistors and p-channel nanostructure transistors through vias 154 and the contact plugs 148A2 and 148B2, in accordance with some embodiments.

The semiconductor structure 100 may undergo further frontside BEOL processes to form various interconnection conductive features (not shown) over the semiconductor structure 100, such as frontside second metal layer (F_M2) to frontside tenth metal layer (F_M10) and vias between neighboring two metal layers.

FIGS. 3G-1 and 3G-2 illustrate cross-sectional views of the semiconductor structure 100 after flipping the semiconductor structure 100 and a planarization process, in accordance with some embodiments.

The semiconductor structure 100 is flipped upside down, as shown FIGS. 3G-1 and 3G-2, in accordance with some embodiments. In some embodiments, a carrier substrate (not shown) may be formed over and seal the frontside of the semiconductor structure 100 before flipping the semiconductor structure 100 to protect the components of the semiconductor structure 100 during subsequent backside processes. After flipping the semiconductor structure 100, the backside surface of the substrate 102 (the backside of the semiconductor structure 100) faces upward, in accordance with some embodiments.

The substrate 102 is removed from the backside of the semiconductor structure 100 using a planarization process such as CMP, an etching process, or a combination thereof until the lower fin elements 103N and 103P and the isolation structure 110 are exposed, as shown in FIGS. 3G-1 and 3G-2, in accordance with some embodiments.

FIGS. 3H-1 and 3H-2 illustrate cross-sectional views of the semiconductor structure 100 after the formation of the contact openings 164A and 164B, in accordance with some embodiments.

A patterning process is performed on the lower fin elements 103N and 103P, the semiconductor isolation layers 124 and the dielectric isolation layers 126 to form contact openings 164A and 164B using photolithography and etching processes, as shown in FIGS. 3H-1 and 3H-2, in accordance with some embodiments. The patterning process includes forming a patterned mask layer 160 over the backside of the semiconductor structure 100, in accordance with some embodiments. The patterned mask layer 160 has opening patterns 162A and 162B which expose the lower fin elements 103N and 103P and correspond to the source/drain features 128N and 128P used for the Vdd/Vss nodes, in accordance with some embodiments.

In some embodiments, the dimension D2A of the contact openings 164A in the X direction is less than the dimension D2B of the contact openings 164B in the X direction by about 1 nm to about 10 nm. In some embodiments, the dimension D2A is in a range from about 10 nm to about 15 nm. In some embodiments, the dimension D2B is in a range from about 12 nm to about 20 nm.

In some embodiments, the patterned mask layer 160 is a patterned photoresist layer. For example, a photoresist may be formed over the backside of the semiconductor structure 100 such as by using spin-on coating, and patterned by exposing the photoresist to light using an appropriate photomask. Exposed or unexposed portions of the photoresist may be removed depending on whether a positive or negative resist is used. In alternative embodiments, the patterned mask layer 160 is a patterned hard mask layer. The patterned mask layer 160 may be made of metal oxide (e.g., AlO, TiO, LaO, HfO, etc.), a nitrogen-free anti-reflection layer (NFARL), carbon-doped silicon dioxide (e.g., SiO₂:C), titanium nitride (TiN), boron nitride (BN), a multilayer thereof, another suitable material, or a combination thereof. For example, a material for the patterned mask layer 160 is deposited, and a patterned photoresist layer may be formed over the material for the patterned mask layer 160 using the photolithography process described above. The material for the patterned mask layer 160 may be etched using the patterned photoresist layer to form the patterned mask layer.

The patterning process also includes performing an etching process using the patterned mask layer 160 to remove the portions of the lower fin elements 103N and 103P, the semiconductor isolation layers 124, the dielectric isolation layers 126 corresponding to the opening patterns 162A and 162B and the underlying source/drain features 128N and 128P, thereby forming the contact openings 164A and 164B, in accordance with some embodiments. The etch process may include dry etching such as RIE, NBE, ICP etch, CPP etch, another suitable method, or a combination thereof.

In some embodiments, the contact openings 164A and 164B have downward tapering sidewalls. In the first cell region C1, the bottom surfaces of the contact openings 164A are located at a position that is substantially level with or lower than the top surfaces of the topmost nanostructures 108 (in current cross-sectional view), but not lower than the top surface of the second topmost nanostructures 108 (in current cross-sectional view), in accordance with some embodiments. In the first cell region C1, the bottom surfaces of the contact openings 164B are located at a position that is substantially level with or lower than the bottom surface of the second topmost nanostructures 108 (in current cross-sectional view), in accordance with some embodiments.

Because the second cell region C2 has a greater contact-to-poly pitch (CPP) than the first cell region C1, the process window for forming the contact opening 164B may be large without increasing the risk of leakage between the subsequently formed backside contact plug and the final gate stack (especially leakage between the contact plug and the tailing portion of the final gate stack), and without causing the backside contact plug to come into contact with the barrier layers L1.

Due to the characteristics of the etching process, the larger the dimension of the contact opening (or opening pattern), the greater the etching amount. As a result, the contact openings 164B are formed to have a greater dimension D2B and a deeper depth D4B, while the contact openings 164A are formed to have a smaller dimension D2A and a shallower depth D4A, in accordance with some embodiments. In some embodiments, the depth D4A (the dimension in the Z direction) of the contact openings 164A is less than the depth D4B (the dimension in the Z direction) of the contact openings 164B by about 2 nm to about 25 nm. In some embodiments, the dimension D3A of the contact openings 164A in the Y direction is less than the dimension D3B of the contact openings 164B in the Y direction.

FIGS. 3I-1 and 3I-2 illustrate cross-sectional views of the semiconductor structure 100 after the formation of backside contact plug 166A and 166B and power rails 170, in accordance with some embodiments. FIGS. 3I-1 and 3I-2 illustrate that the frontside of the semiconductor structure 100 faces upward.

Backside contact plugs 166A and 166B are formed in the contact openings 164A and 164B, respectively, as shown in FIGS. 3I-1 and 3I-2, in accordance with some embodiments. The backside contact plugs 166A and 166B land on and extend into the source/drain features 128N and 128P, in accordance with some embodiments. The contact plugs 166A and 166B may have a multilayer structure. For example, silicide layers 168 are formed on the backside surfaces of the source/drain features 128N and 128P exposed from the contact openings 164A and 164B.

In some embodiments, the silicide layers 168 are made of WSi, NiSi, TiSi and/or CoSi. In some embodiments, the formation of the silicide layers 168 includes depositing a metal material followed by one or more annealing processes. The semiconductive material (e.g., Si or SiGe) from the source/drain features 128N and 128P reacts with the metal material to form the silicide layers 168, in accordance with some embodiments. The unreacted metal material is then removed using a cleaning process.

One or more conductive materials are deposited on the silicide layers 168 to overfill the contact openings 164A and 164B. For example, one or more conductive materials include a barrier/adhesive layer and a metal bulk layer on the barrier/adhesive layer. In some embodiments, the barrier layer may be made of tantalum (Ta), tantalum nitride (TaN), titanium (Ti), titanium nitride (TiN), cobalt tungsten (CoW), another suitable material, or a combination thereof. In some embodiments, the metal bulk layers are made of one or more conductive materials, such as cobalt (Co), nickel (Ni), tungsten (W), titanium (Ti), tantalum (Ta), copper (Cu), rhodium (Rh), iridium (Ir), platinum (Pt), aluminum (Al), ruthenium (Ru), molybdenum (Mo), or a combination thereof.

In some embodiments, one or more conductive materials are deposited using CVD, PVD, e-beam evaporation, ALD, electroplating (ECP), electroless deposition (ELD), another suitable method, or a combination thereof. In some embodiments, the metal bulk layer is formed using a selective deposition technique such as cyclic CVD process or ELD process, and it is not necessary to form the barrier/adhesive layer before depositing the metal bulk material. The one or more conductive materials over the upper surface of the isolation structure 110 are planarized using, for example, CMP. In some embodiments, the patterned mask layer 160 is also removed.

In some embodiments, in the second cell region C2, the dimension of the backside contact plugs 166B in the X direction (substantially equal to dimension D2B) is greater than the width W2B of the frontside contact plugs 148B1 in the X direction. In the first cell region C1, the dimension of the backside contact plugs 166A in the X direction (substantially equal to dimension D2A) may be less than, equal to or greater than the width W2A of the frontside contact plugs 148A1 in the X direction.

In some embodiments, the contact plug 166A has a dimension D5A measured from the top surface (i.e., the bottom surface in the current cross-sectional view) of the source/drain features 128N (or 128P) to the bottom (i.e., the top in the current cross-sectional view) of the silicide 168. The dimension D5A is in a range from about 3 nm to about 10 nm.

In some embodiments, the contact plug 166B has a dimension D5B measured from the top surface (i.e., bottom surface in the current cross-sectional view) of the source/drain features 128N (or 128P) to the bottom (i.e., the top in the current cross-sectional view) of the silicide 168. The dimension D5B is in a range from about 10 nm to about 40 nm. The dimension D5B is greater than the dimension D5A by about 2 nm to about 25 nm.

In some embodiments, the contact plug 166A is separate from the contact plug 148A1. In some embodiments, the contact plug 166B is separate from the contact plug 148B1. In some embodiments, the distance between the contact plug 148A1 and the contact plug 166A is greater than the distance between the contact plug 148B1 and the contact plug 166B.

An intermetal dielectric layer (not shown) is formed over the backside of semiconductor structure 100, and a backside first metal layer (B_M1) is formed in or through the intermetal dielectric layer, as shown in FIGS. 3I-1 and 3I-2, in accordance with some embodiments. The backside first metal layer includes backside power rails 170, in accordance with some embodiments.

The Vss backside power rails 170 are electrically connected to the Vss node (e.g., source terminals) of the n-channel nanostructure transistors through the contact plugs 166A and 166B, in accordance with some embodiments. The Vdd backside power rails 170 are electrically connected to the Vdd node (e.g., source terminals) of the p-channel nanostructure transistors through the contact plugs 166A and 166B, in accordance with some embodiments. In some embodiments, the backside first metal layer includes no signal lines.

In accordance with the embodiments of the present disclosure, the first cell region C1 with a smaller contact-to-poly pitch CPP1 has a shallower backside contact plug 166A, which may prevent the backside contact plug 166A from landing on the barrier layers L1 and allow the source/drain features 128N and 128P to have a greater remaining volume to imparting stress and/or strain to the channel regions. Meanwhile, the second cell region C2 with a larger contact-to-poly pitch CPP2 has a deeper backside contact plug 166B, which may increase the landing area of the contact plug 166B with the bulk layer L2 of the source/drain features 128N and 128P and/or reduce the current path. Therefore, the respective performances of the resulting semiconductor devices in the first cell region C1 and the second cell region C2 may be improved, e.g., higher DC performance.

In addition, by using the opening patterns 162A and 162B with different sizes, the depth of the contact opening 164A and the depth of the contact opening 164B can be independently controlled in one patterning process, thereby forming the contact plugs 166A and 166B with respective desirable depths. As a result, the manufacturing cost and/or difficulty may be improved.

The embodiments of FIGS. 3A-1 through 3I-2 are discussed in the context of the nano-sheet transistors, the embodiments of the present disclosure may be applied to nanowire transistors, fork-sheet transistors, CFET (complementary FET), and the like.

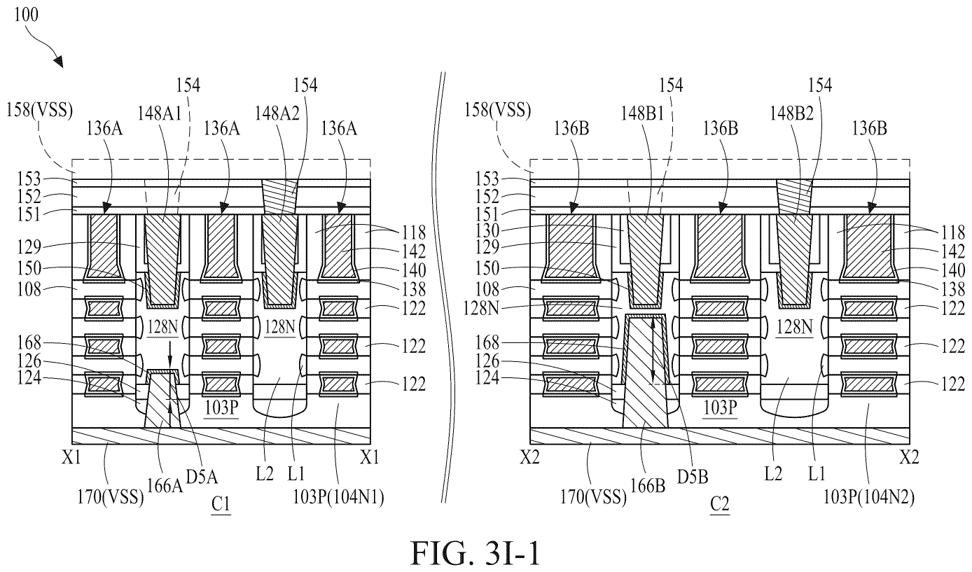

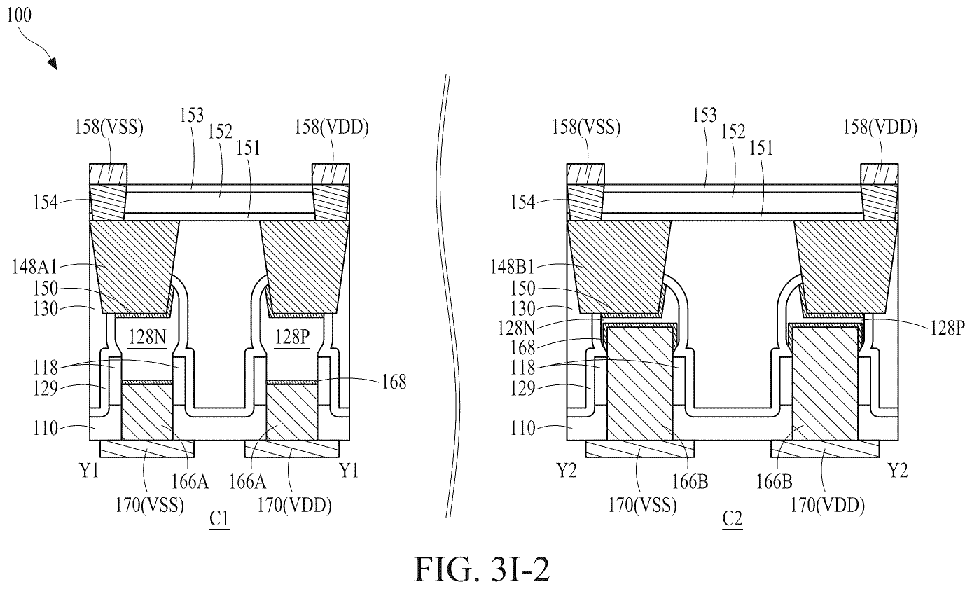

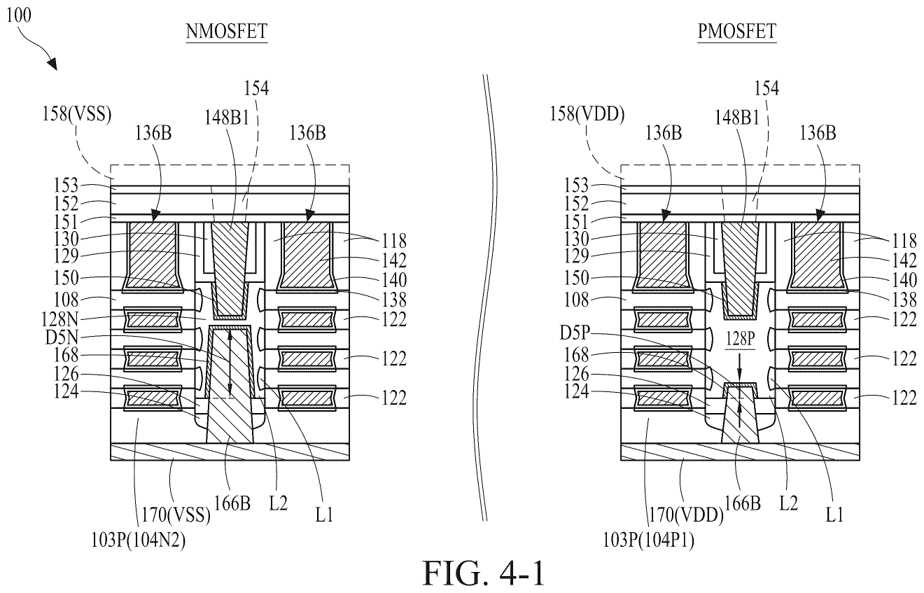

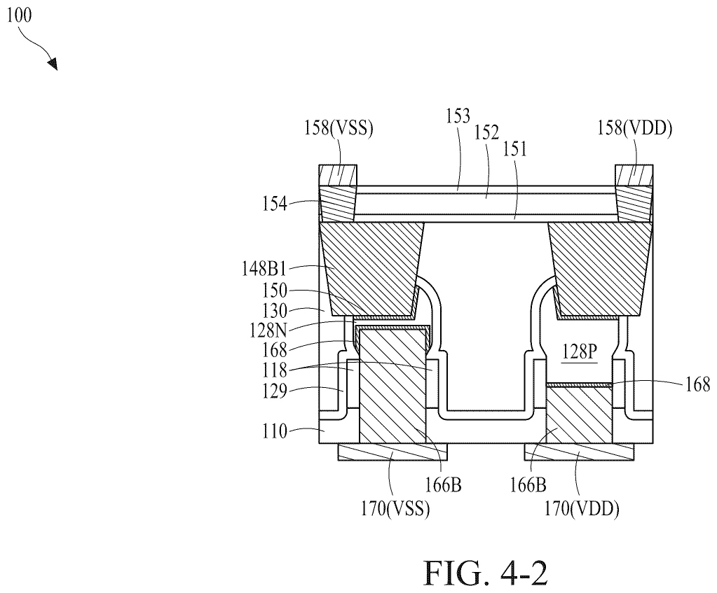

FIGS. 4-1 and 4-2 are a modification of the semiconductor structure 100 of FIGS. 3I-1 and 3I-2, in accordance with some embodiments of the disclosure. The embodiments of FIGS. 4-1 and 4-2 are similar to the embodiments of FIGS. 3A-1 to 3I-2, except that the depth of the backside contact plug 166B of the n-channel nanostructure transistors NMOSFET is different than the depth of the backside contact plug 166B of the p-channel nanostructure transistors PMOSFET.

In some embodiments, the performance of the p-channel nanostructure transistor PMOSFET may be boosted by imparting stress and/or strain to the channel regions using the p-type source/drain features 128P. After the formation of the backside contact plugs 168B, the source/drain feature 128P has more remaining volume than the source/drain feature 128N, as shown in FIGS. 4-1 and 4-2. In some embodiments, the backside contact plug 166B of the p-channel nanostructure transistor PMOSFET is formed to have a smaller dimension in the X direction and a shallower depth than the dimension in the X direction and the depth of the backside contact plug 166B of the n-channel nanostructure transistor NMOSFET.

The contact plug 166A of the n-channel nanostructure transistor NMOSFET has a dimension D5N measured from the top surface (i.e., the bottom surface in the current cross-sectional view) of the source/drain features 128N (or 128P) to the bottom (i.e., the top in the current cross-sectional view) of the silicide 168. The dimension D5N is in a range from about 15 nm to about 40 nm. The contact plug 166A of the p-channel nanostructure transistor PMOSFET has a dimension D5P measured from the top surface (i.e., the bottom surface in the current cross-sectional view) of the source/drain features 128N (or 128P) to the bottom (i.e., the top in the current cross-sectional view) of the silicide 168. The dimension D5P is in a range from about 10 nm to about 20 nm. The dimension D5P is less than the dimension D5N by about 2 nm to 10 nm.

In some embodiments, the distance between the contact plug 148B1 and the contact plug 166B which land on the source/drain feature 128N is less than the distance between the contact plug 148B1 and the contact plug 166B which land on the source/drain feature 128P. In some embodiments, the distance between the barrier layers L1 and the contact plug 166B of the n-channel nanostructure transistors NMOSFET is less than the distance between the barrier layers L1 and the contact plug 166B of the p-channel nanostructure transistors PMOSFET.

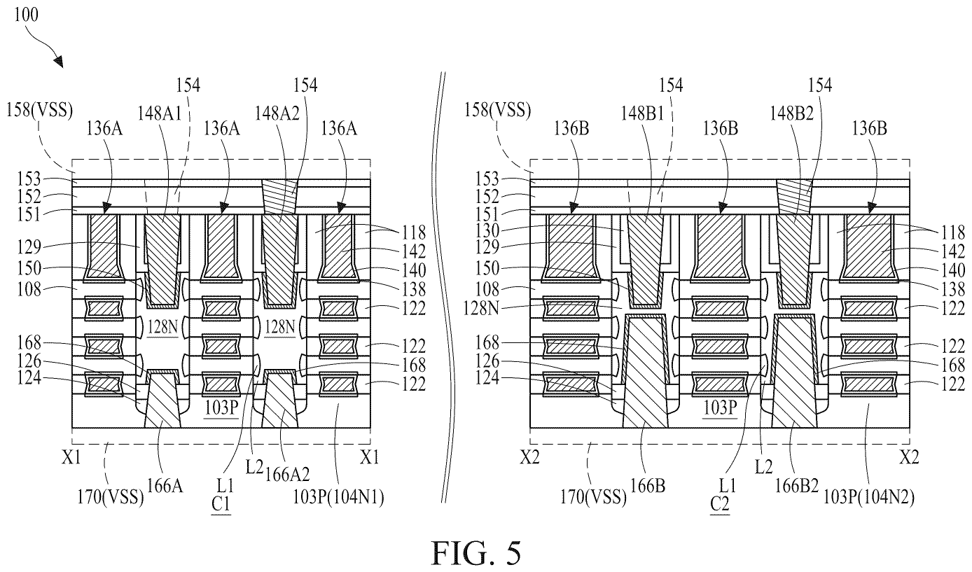

FIG. 5 is a modification of the semiconductor structure 100 of FIG. 3I-1, in accordance with some embodiments of the disclosure. The embodiments of FIG. 5 are similar to the embodiments of FIGS. 3A-1 to 3I-2, except that backside contact plug 168A2 and 166B2 are formed on the non-Vdd/Vss nodes (e.g., drain terminals). In some embodiments, the backside metal layer further includes signal lines (not shown) which are electrically connected to the non-Vdd/Vss nodes of the n-channel nanostructure transistors and p-channel nanostructure transistors through the backside contact plugs 166A2 and 166B2, in accordance with some embodiments. Two backside power rails 170 are shown as dash lines, which indicates that they are not in the cross-sectional view. The formation and dimension of the backside contact plugs 166A2 and 166B2 may has similar as the backside contact plugs 166A and 166B, and thus will not be repeated.

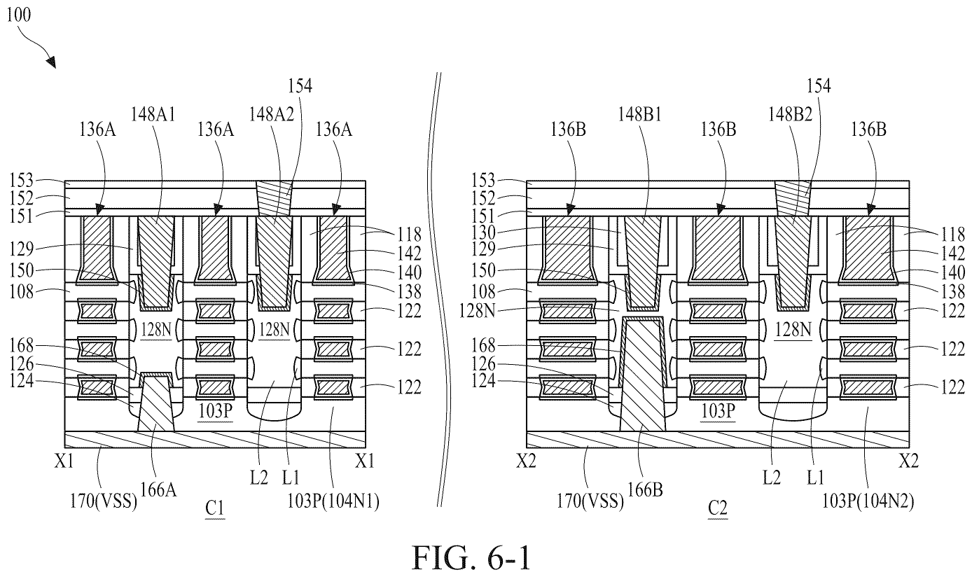

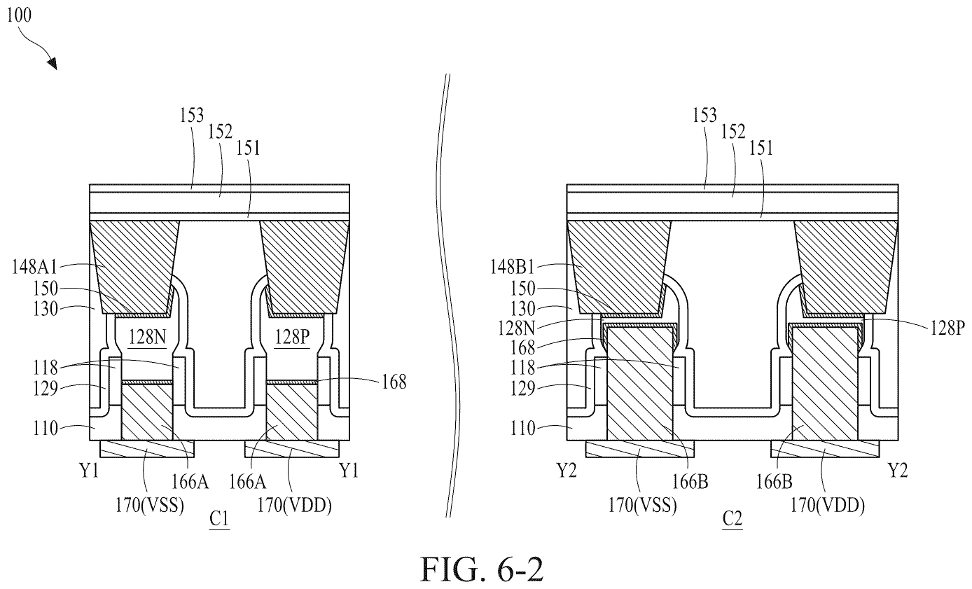

FIGS. 6-1 and 6-2 are a modification of the semiconductor structure 100 of FIGS. 3I-1 and 3I-2, in accordance with some embodiments of the disclosure. The embodiments of FIGS. 6-1 and 6-2 are similar to the embodiments of FIGS. 3A-1 to 3I-2, except no frontside power rail 158 formed to connect the frontside contact plugs 148A1 and 148B1. Therefore, the routing density of the frontside metal layer may be relaxed. In some embodiments, the semiconductor structure 100 is powered only from the backside. In some embodiments, the frontside contact plugs 148A1 and 148B1 are used as dummy patterns, which may improve the process stability of the photolithography process and/or the planarization process for forming the contact plugs.

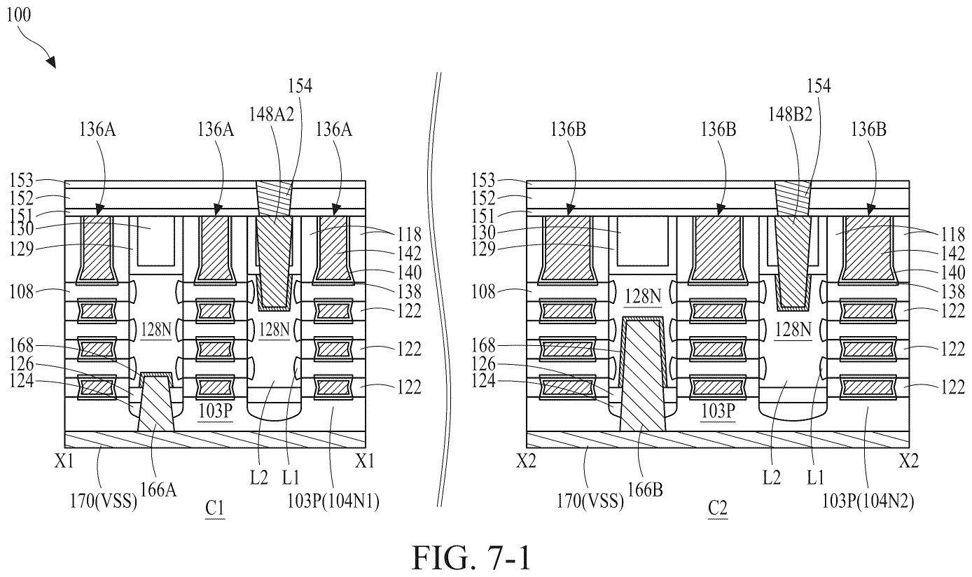

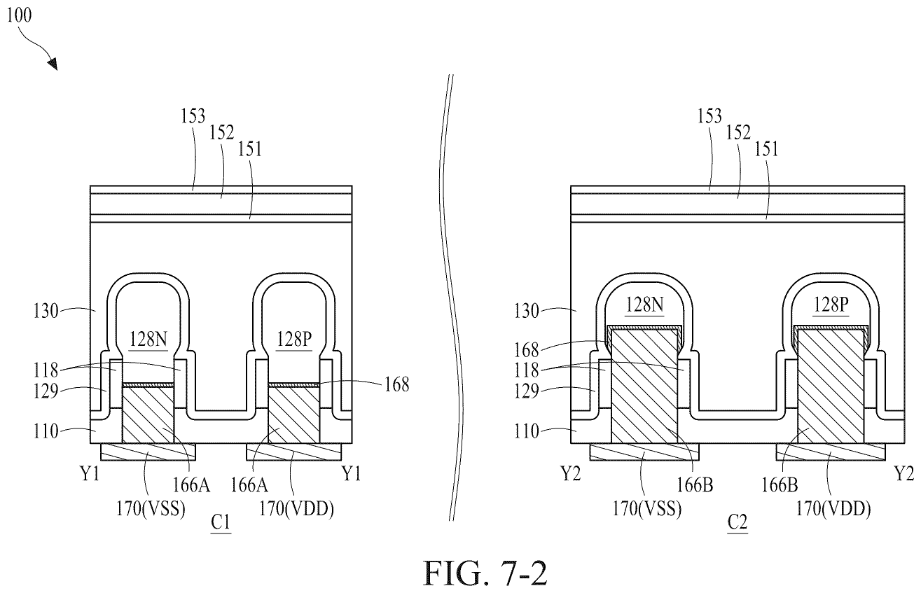

FIGS. 7-1 and 7-2 are a modification of the semiconductor structure 100 of FIGS. 3I-1 and 3I-2, in accordance with some embodiments of the disclosure. The embodiments of FIGS. 7-1 and 7-2 are similar to the embodiments of FIGS. 3A-1 to 3I-2, except that no frontside contact plugs 148A1 and 148B1 are formed.

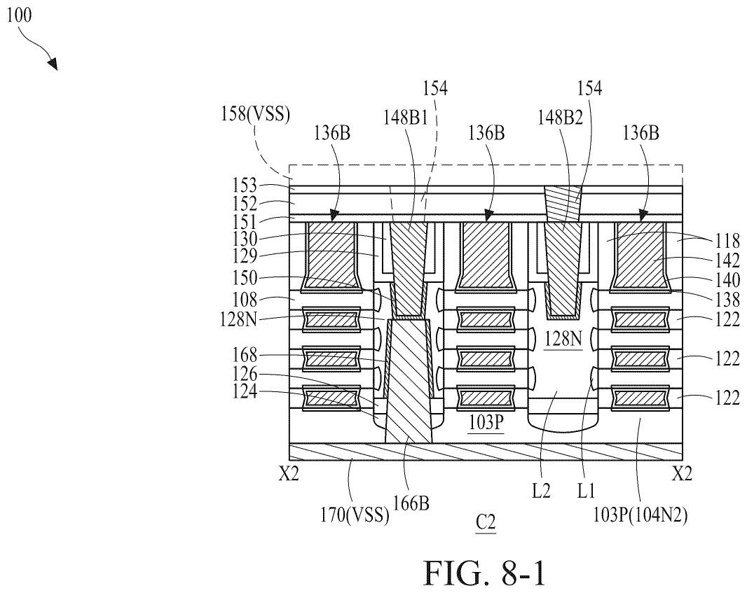

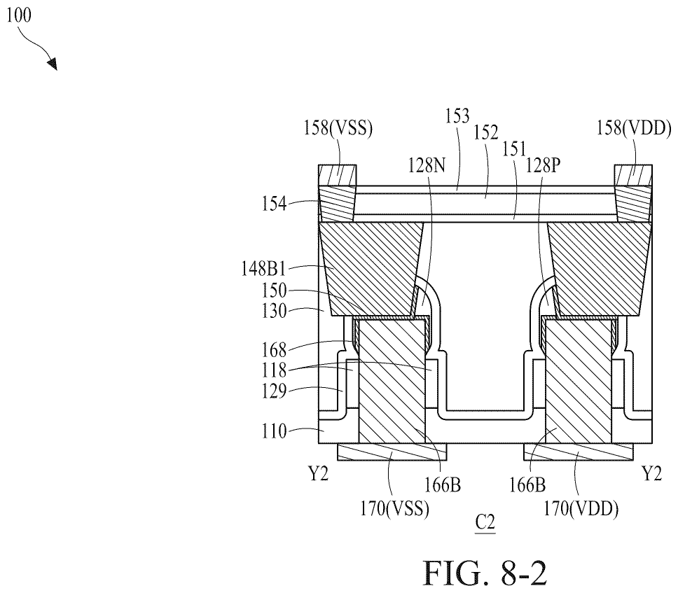

FIGS. 8-1 and 8-2 are a modification of the semiconductor structure 100 of FIGS. 3I-1 and 3I-2, in accordance with some embodiments of the disclosure. The embodiments of FIGS. 8-1 and 8-2 are similar to the embodiments of FIGS. 3A-1 to 3I-2, except that backside contact plugs 166B extend to and are in direct contact with the frontside contact plug 148B1.

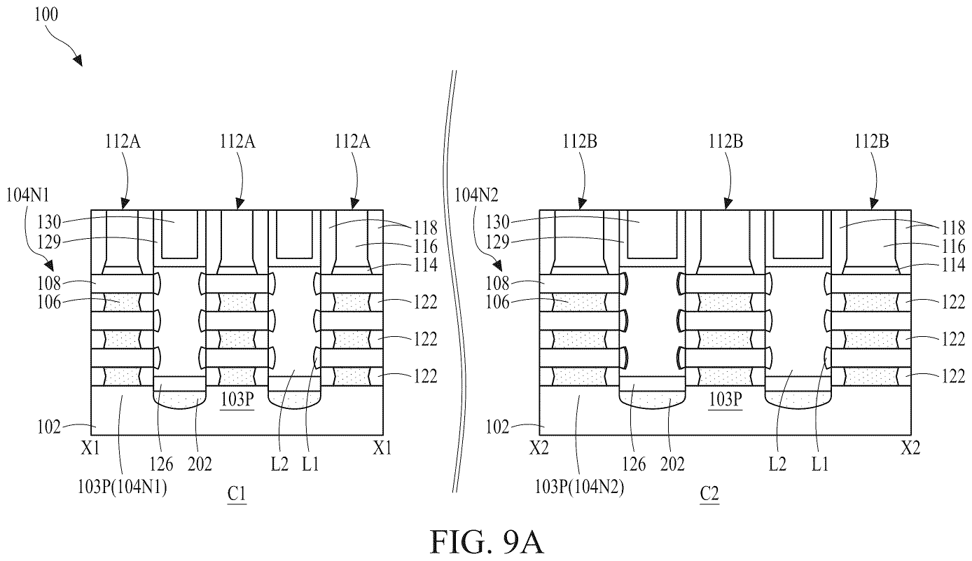

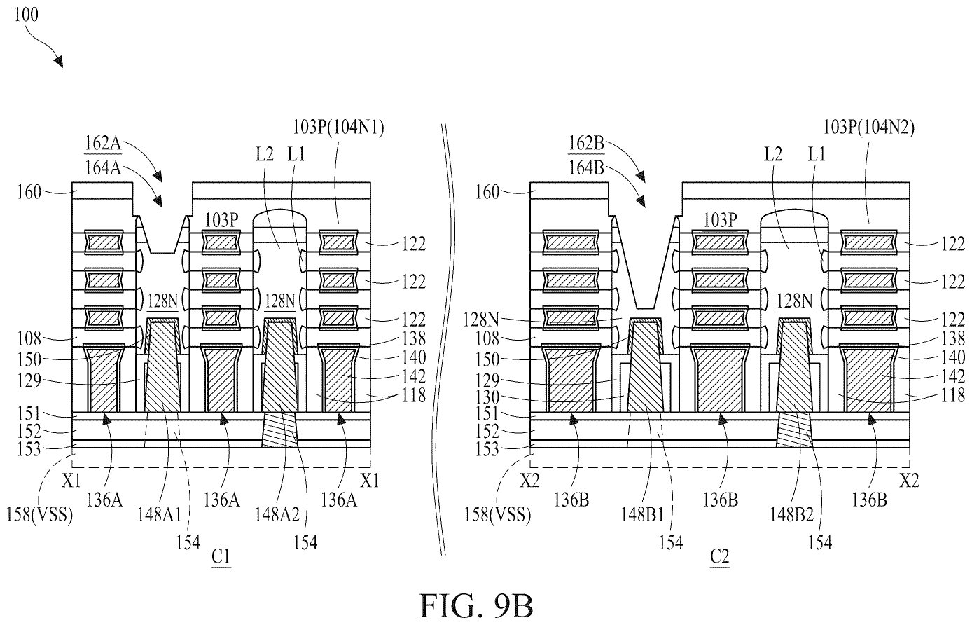

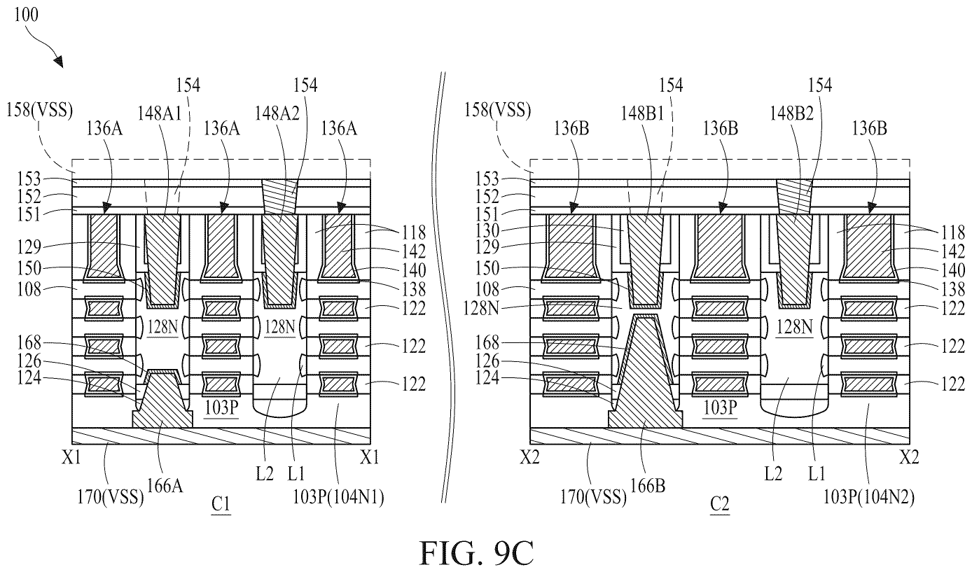

FIGS. 9A to 9C are cross-sectional views illustrating the formation of the semiconductor structure 100 of FIG. 2 at various intermediate stages corresponding to line X1-X1, in accordance with some embodiments of the disclosure. The embodiments of FIGS. 9A to 9C are similar to the embodiments of FIGS. 3A-1 to 3I-2, except that backside contact plugs 166A and 166B have a T-shape profile.

After the inner spacer layers 122 are formed, sacrificial layers 202 are formed in the source/drain recesses 120 on the lower fin elements 103N and 103P, and the dielectric isolation layers 126 are formed on the sacrificial layers 202, as shown in FIG. 9A, in accordance with some embodiments. In some embodiments, the sacrificial layers 202 are made of an epitaxial semiconductor material such as silicon germanium or germanium, formed by MBE, MOCVD, or VPE, another suitable technique, or a combination thereof. The sacrificial layers 202 and the lower fin elements 103N and 103P are made of different materials and have a great difference in etching selectivity.

The steps described above with respect to FIGS. 3C-1 to 3H-2 are performed, thereby forming the source/drain features 128N and 128P, the contact etching stop layer 129, the first interlayer dielectric layer 130, the final gate stacks 136A and 136B, the frontside contact plugs 148A and 148B, the vias 154 and the frontside metal layer, as shown in FIG. 9B, in accordance with some embodiments. Afterward, the substrate 102 is removed, the patterned mask layer 160 is formed on the semiconductor structure 100, and an etching process is performed using the patterned mask layer 160, as shown in FIG. 9B, in accordance with some embodiments. In some embodiments, the dimension of the opening patterns 162A in the X direction is greater than the dimension of the underlying sacrificial layers 202 in the X direction, and the dimension of the opening patterns 162B in the X direction is greater than the dimension of the underlying sacrificial layers 202 in the X direction.

Because the sacrificial layers 202 and the lower fin elements 103N and 103P have a great difference in etching selectivity, the lower fin elements 103N and 103P consume little or nothing in the step of the etching process etching the sacrificial layers 202, in accordance with some embodiments. As a result, the contact openings 164A and 164B are formed self-aligned to the sacrificial layers 202 and the source/drain features 128N and 128P without increasing the risk leakage between the backside contact plug and the final gate stack.

In some embodiments, the contact openings 164A and 164B are formed to have wider portions and narrower portions under the wider portion, in accordance with some embodiments. The wider portions of the contact openings 164A and 164B may be helpful in reducing the resistance of backside contact plugs. The narrower portions of the contact openings 164A and 164B may be kept at a sufficient distance from the final gate stacks 136A and 136B, thereby reducing the parasitic capacitance between the backside contact plugs and the final gate stack, and/or reducing the risk of leak between the backside contact plugs and the final gate stack.

The steps as described above in FIGS. 3I-1 and 3I-2 are performed, thereby forming the backside contact plugs 166A and 166B and the backside metal layer, as shown in FIG. 9C, in accordance with some embodiments.

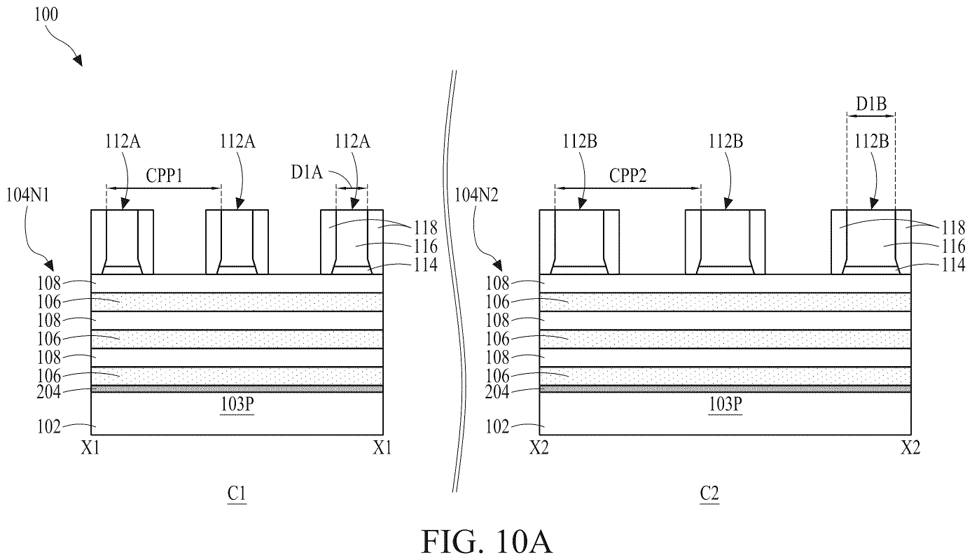

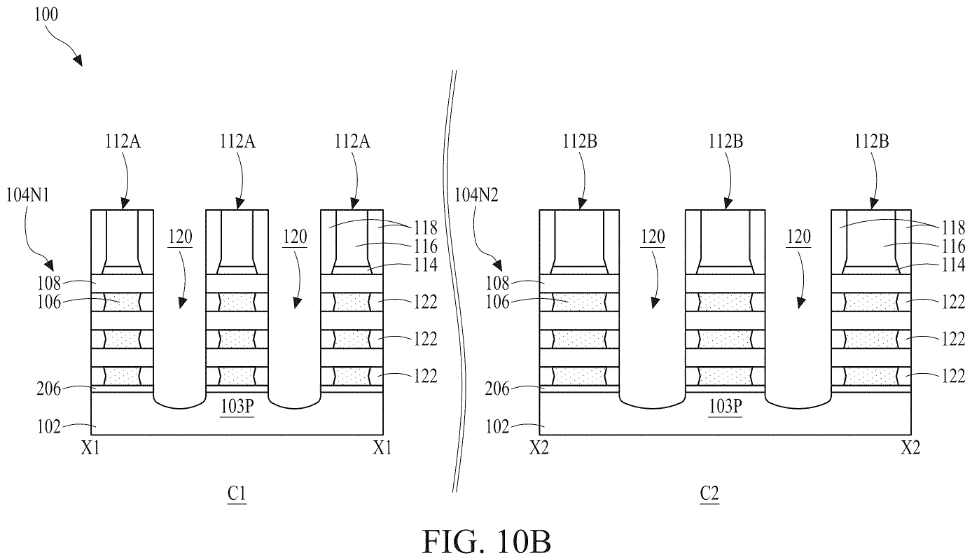

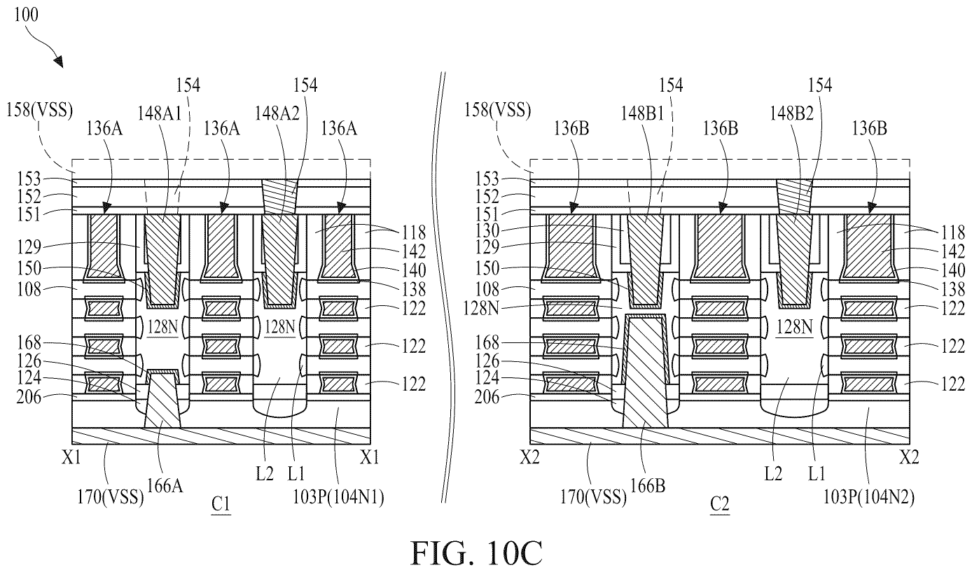

FIGS. 10A to 10C are cross-sectional views illustrating the formation of the semiconductor structure 100 of FIG. 2 at various intermediate stages corresponding to line X1-X1, in accordance with some embodiments of the disclosure. The embodiments of FIGS. 10A to 10C are similar to the embodiments of FIGS. 3A-1 to 3I-2, except that an isolation layer is formed under the final gate stacks 136A and 136B.

The active region 104N and 104P further includes a sacrificial layer 204 between the bottommost first semiconductor layer 106 and the substrate 102, as shown in FIG. 10A, in accordance with some embodiments. In some embodiments, the sacrificial layer 204 is made of the same material as the first semiconductor layers 106, e.g., SiGe. In some embodiments, the sacrificial layer 204 is a SiGe layer with a higher germanium concentration than the first semiconductor layers 106.

After the source/drain recesses 120 are formed, the sacrificial layer 204 is removed to form a gap, and an isolation layer 206 is formed to fill the gap, as shown in FIG. 10B, in accordance with some embodiments. The sacrificial layer 204 is replaced with an isolation layer 206, in accordance with some embodiments. In some embodiments, the sacrificial layer 204 is made of a dielectric material, such as silicon nitride (SiN), silicon oxide (SiO₂), silicon carbide (SiC), silicon oxynitride (SiON), silicon carbon nitride (SiCN), silicon oxycarbonitride (SiOCN), and/or oxygen-doped silicon carbonitride (Si(O)CN), or high-k dielectric material (e.g., with dielectric constant greater than about 7.9) such as LaO, AlO, AlON, ZrO, HfO, ZnO, ZrN, ZrAlO, TiO, TaO, YO, or TaCN.

In some embodiments, the isolation layer 206 is formed by depositing a dielectric material to overfill the gap, and then etching back the dielectric material to remove the dielectric material outside the gap. In some embodiments, the deposition process includes ALD, CVD (such as PECVD, LPCVD or HARP), another suitable technique, or a combination thereof.

The steps described above in FIGS. 3C-1 to 3I-2 are performed, thereby forming the source/drain features 128N and 128P, the contact etching stop layer 129, the first interlayer dielectric layer 130, the final gate stacks 136A and 136B, the frontside contact plugs 148A and 148B, the vias 154 the frontside metal layer, the backside contact plugs 166A and 166B and the backside metal layer, as shown in FIG. 10C, in accordance with some embodiments. The isolation layer 206 directly under the final gate stacks 136A and 136B may prevent the leakage caused by the planner transistor formed from the lower fin element 103N or 103P.

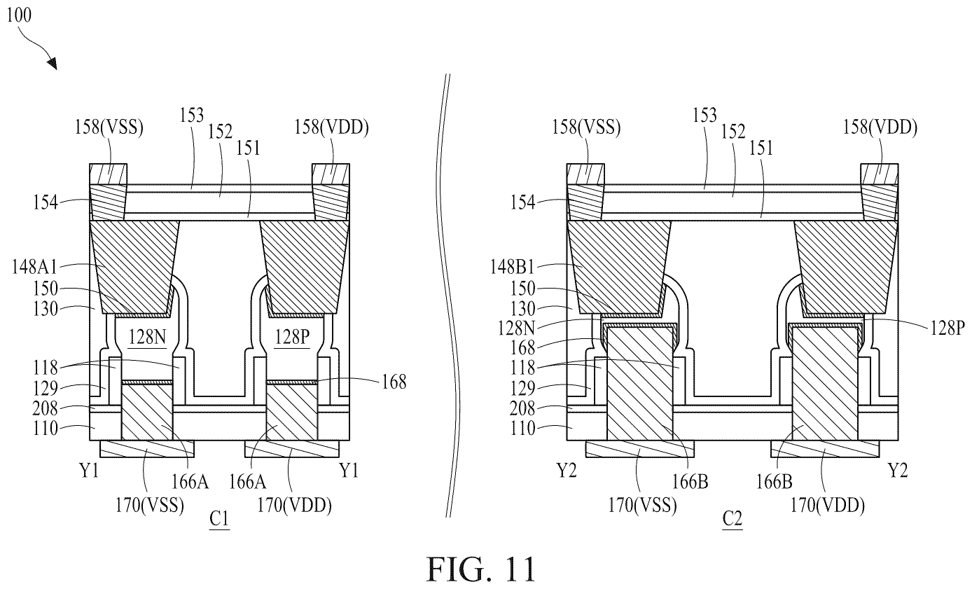

FIG. 11 is a modification of the semiconductor structure 100 of FIG. 3I-2, in accordance with some embodiments of the disclosure. The embodiments of FIG. 11 are similar to the embodiments of FIGS. 3A-1 to 3I-2, except that a mask layer 208 is formed on the isolation structure 110 after the dummy gate structures 112A and 112B are formed. The mask layer 208 and the isolation structure 110 are made of different materials and have a great difference in etching selectivity, in accordance with some embodiments.

The mask layer 208 is made of dielectric material, e.g., silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O)CN), or high-k dielectric material (e.g., with dielectric constant greater than about 7.9) such as LaO, AlO, AlON, ZrO, HfO, ZnO, ZrN, ZrAlO, TiO, TaO, YO, or TaCN. In some embodiments, the mask layer 208 may protect the isolation structure 110 from being recessed in the etching process for forming the source/drain recesses 120, which may improve the total capacitance of the cell regions C1 and C2.

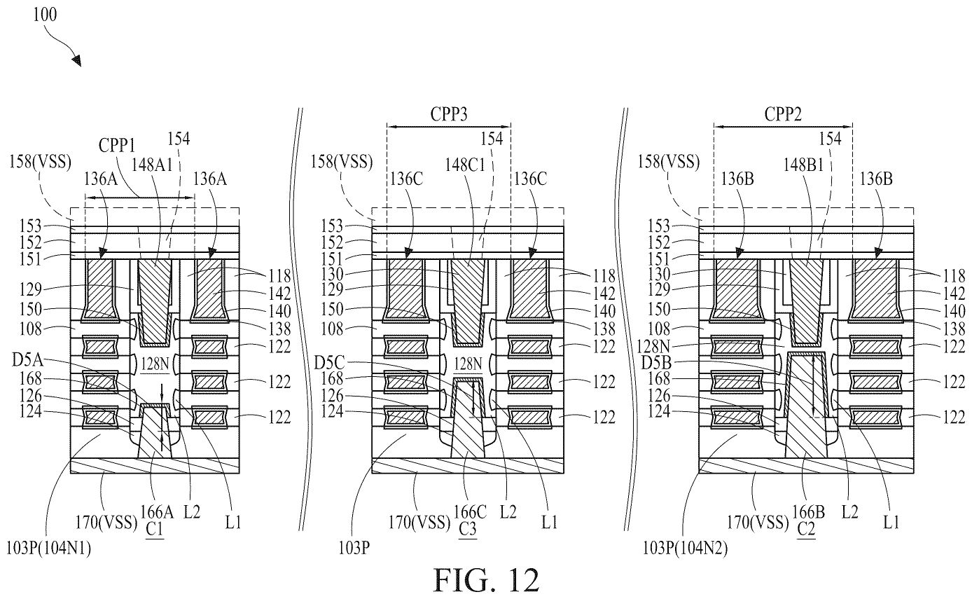

FIG. 12 is a modification of the semiconductor structure 100 of FIG. 3I-1, in accordance with some embodiments of the disclosure. The embodiments of FIG. 11 are similar to the embodiments of FIGS. 3A-1 to 3I-2, except that the semiconductor structure 100 (or the substrate) is further divided as a third cell region C3, in accordance with some embodiments. The third cell region C3 has a contact-poly pitch CPP3 between the contact-poly pitch CPP1 of the first cell region C1 and the contact-poly pitch CPP1 of the second cell region C2.

In some embodiments, the backside contact plug 166C in the third cell region C3 is formed to have a dimension in the X direction between the dimension of the backside contact plug 166A in the X direction and the dimension of the backside contact plug 166B in the X direction. The backside contact plug 166C has a dimension D5C measured from the top surface (i.e., bottom surface in the current cross-sectional view) of the source/drain features 128N (or 128P) to the bottom (i.e., the top in the current cross-sectional view) of the silicide 168. In some embodiments, the dimension D5C is between the dimension D5A and the dimension D5B. In some embodiments, the silicide layers 168 of the contact plug 166C is separate from the barrier layers L1 of the source/drain features 128N (and 128P).

As described above, the aspect of the present disclosure is directed to a semiconductor structure with a backside power rail architecture. The semiconductor structure includes cell regions with at least two different contact-poly pitches. The first cell region C1 with a smaller contact-to-poly pitch CPP1 has a shallower backside contact plug 166A, while the second cell region C2 with a large contact-to-poly pitch CPP2 has a deeper backside contact plug 166B. As a result, the first cell region C1 may have the source/drain features 128N/P with a greater volume to impart strain or stress to the channel region, while the second cell region C2 may have a lower contact resistance and lower parasitic resistance. Therefore, the performance of the resulting semiconductor devices may be improved, e.g., higher DC performance.

Embodiments of a semiconductor structure and the method for forming the same may be provided. The method for forming a first backside contact plug on a source/drain terminal in a first cell region, and a second backside contact plug on a source/drain terminal in a second cell region. The contact-to-poly pitch of the first cell region is less than the contact-to-poly pitch of the second cell region. Therefore, the respective performances of the resulting semiconductor devices in the first cell region and the second cell region may be improved.

In some embodiments, a method for forming a semiconductor structure is provided. The method includes forming a first transistor and a second transistor on a substrate. The first transistor includes a first source/drain feature adjoining first channel layers and a first gate stack surrounding the first channel layers. The second transistor includes a second source/drain feature adjoining second channel layers, and a second gate stack surrounding the second channel layers. The method further includes forming a first contact plug that partially passes through the first source/drain feature from a backside surface of the first source/drain feature, and forming a second contact plug that partially passes through the second source/drain feature from a backside surface of the second source/drain feature. The first contact plug is shallower than the second contact plug.

In some embodiments, a method for forming a semiconductor structure is provided. The method includes forming a stack of alternating first semiconductor layers and second semiconductor layers over a substrate, patterning the stack into a first active region and a second active region, forming a first source/drain feature and a second source/drain feature respectively through the first active region and the second active region, removing the first semiconductor layers of the first active region and the second active region, forming a first gate stack and second gate stack respectively surrounding the second semiconductor layers of the first active region and the second active region, flipping the substrate upside down, and forming a first contact opening and a second contact opening respectively through the first source/drain feature and the second source/drain feature. A dimension of the first contact opening in a vertical direction is less than a dimension of the second contact opening in the vertical direction.

In some embodiments, a semiconductor structure is provided. The semiconductor structure includes a first circuit in a first cell region and a second circuit in a second cell region. The first circuit includes first active regions and first gate stacks across the first active regions, and a first contact plug electrically connecting a source/drain terminal of the first circuit to a first backside power rail. The second circuit includes second active regions and second gate stacks across the second active regions, and a second contact plug electrically connecting a source/drain terminal of the second circuit to a second backside power rail. The second contact plug is wider than the first contact plug, and the second contact plug is deeper than the first contact plug.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
forming a first transistor and a second transistor on a substrate, wherein the first transistor includes a first source/drain feature adjoining first channel layers and a first gate stack surrounding the first channel layers, and the second transistor includes a second source/drain feature adjoining second channel layers, and a second gate stack surrounding the second channel layers;
forming a first contact plug that partially passes through the first source/drain feature from a backside surface of the first source/drain feature; and
forming a second contact plug that partially passes through the second source/drain feature from a backside surface of the second source/drain feature, wherein the first contact plug is shallower than the second contact plug in a vertical direction.

2. The method for forming the semiconductor structure as claimed in claim 1, wherein the first gate stack and the second gate stack extend in a first horizontal direction, and the first gate stack is narrower than the second gate stack in a second horizontal direction that is perpendicular to the first horizontal direction.

3. The method for forming the semiconductor structure as claimed in claim 1, wherein the first source/drain feature is doped with a p-type dopant, and the second source/drain feature is doped with an n-type dopant.

4. The method for forming the semiconductor structure as claimed in claim 1, further comprising:
flipping the substrate upside down;
removing the substrate; and
forming a patterned mask layer having a first opening pattern overlapping the first source/drain feature and a second opening pattern overlapping the second source/drain feature, wherein:
the first gate stack and the second gate stack extend in a first horizontal direction, and
the first opening pattern is narrower than the second opening pattern in a second horizontal direction that is perpendicular to the first horizontal direction.

5. The method for forming the semiconductor structure as claimed in claim 1, wherein the first source/drain feature includes barrier layers on the respective first channel layers and a bulk layer on the barrier layers and having a higher dopant concentration than a dopant concentration of the barrier layers, and the first contact plug extends into the bulk layer and is separated from the barrier layers.

6. The method for forming the semiconductor structure as claimed in claim 1, wherein the second source/drain feature includes barrier layers on the respective second channel layers and a bulk layer on the barrier layers and having a higher dopant concentration than a dopant concentration of the barrier layers, and the second contact plug extends into the bulk layer and is separated from the barrier layers.

7. The method for forming the semiconductor structure as claimed in claim 1, further comprising:
forming a third contact plug that partially passes through the first source/drain feature from a frontside surface of the first source/drain feature; and
forming a fourth contact plug that partially passes through the second source/drain feature from a frontside surface of the second source/drain feature.

8. The method for forming the semiconductor structure as claimed in claim 7, wherein a bottom surface of the third contact plug is substantially level with a bottom surface of the fourth contact plug.

9. The method for forming the semiconductor structure as claimed in claim 1, further comprising:
forming a third contact plug that partially passes through the second source/drain feature from a frontside surface of the second source/drain feature, wherein the second contact plug is in contact with the fourth contact plug.

10. The method for forming the semiconductor structure as claimed in claim 1, wherein the first transistor is formed in a first cell region of the substrate, the second transistor is formed in the second cell region of the substrate, and a cell height of the first cell region is less than a second cell height of the second cell region.

11. A method for forming a semiconductor structure, comprising:
forming a stack of alternating first semiconductor layers and second semiconductor layers over a substrate;
patterning the stack into a first active region and a second active region;
forming a first source/drain feature and a second source/drain feature respectively through the first active region and the second active region;
removing the first semiconductor layers of the first active region and the second active region;
forming a first gate stack and second gate stack respectively surrounding the second semiconductor layers of the first active region and the second active region;
flipping the substrate upside down; and
forming a first contact opening and a second contact opening respectively through the first source/drain feature and the second source/drain feature, wherein a dimension of the first contact opening in a vertical direction is less than a dimension of the second contact opening in the vertical direction.

12. The method for forming the semiconductor structure as claimed in claim 11, further comprising:
forming a sacrificial layer on the substrate, wherein the stack is formed on the sacrificial layer;
recessing the first active region and the second active region to form a first recess and a second recess, respectively, wherein the first source/drain feature and the second source/drain feature are formed in the first recess and the second recess, respectively; and
removing the sacrificial layer to form a gap; and
forming a dielectric layer on the gap.

13. The method for forming the semiconductor structure as claimed in claim 12, wherein the first semiconductor layers and the sacrificial layer are made of SiGe, and a germanium concentration of the first semiconductor layers is lower than a germanium concentration of the sacrificial layer.

14. The method for forming the semiconductor structure as claimed in claim 11, wherein the first active region and the second active region extend in a first horizontal direction, and a dimension of the first contact opening in the first horizontal direction is less than a dimension of the second contact opening in the first horizontal direction.

15. The method for forming the semiconductor structure as claimed in claim 14, further comprising:
forming a first contact plug in the first contact opening and a second contact plug in the second contact opening; and
forming a first power rail on the first contact plug and a second power rail on the second contact plug.

16. The method for forming the semiconductor structure as claimed in claim 11, further comprising:
recessing the first active region and the second active region to form a first recess and a second recess, respectively,
forming a first sacrificial layer and a second sacrificial layer in the first recess and a second recess, respectively, wherein the first source/drain feature and the second source/drain feature are formed on the first sacrificial layer and the second sacrificial layer, respectively;
forming a patterned mask layer having a first opening pattern overlapping the first source/drain feature and a second opening pattern overlapping the second source/drain feature, wherein the first opening pattern is wider than the first sacrificial layer, and the second opening pattern is wider than the second sacrificial layer; and
etching the first source/drain feature and the second source/drain feature using the patterned mask layer to form the first contact opening and the second contact opening.

17. A semiconductor structure, comprising:
a first circuit in a first cell region, the first circuit including first active regions and first gate stacks across the first active regions, and a first contact plug electrically connecting a source/drain terminal of the first circuit to a first backside power rail; and
a second circuit in a second cell region, the second circuit including second active regions and second gate stacks across the second active regions, and a second contact plug electrically connecting a source/drain terminal of the second circuit to a second backside power rail,
wherein the second contact plug is wider than the first contact plug, and the second contact plug is deeper than the first contact plug.

18. The semiconductor structure as claimed in claim 17, further comprising:
a third circuit in a third cell region, the third circuit including third active regions and third gate stacks across the third active regions, and a third contact plug electrically connecting a source/drain terminal of the third circuit to a third backside power rail,
wherein the third contact plug is wider than the first contact plug and narrower than the second contact plug, and the third contact plug is deeper than the first contact plug and shallower than the second contact plug.

19. The semiconductor structure as claimed in claim 17, wherein:
the first circuit further includes a third contact plug electrically connecting to the source/drain terminal of the first circuit to a first front power rail,
the second circuit further includes a fourth contact plug electrically connecting to the source/drain terminal of second first circuit to a second front power rail, and
a distance between the first contact plug and the third contact plug is greater than a distance between the second contact plug and the fourth contact plug.

20. The semiconductor structure as claimed in claim 17, wherein a pitch of the first gate stacks is less than a pitch of the second gate stacks.
